(19) United States
(12) Patent Application Publication
(10) Pub. No.: US 2026/0112318 A1
(43) Pub. Date: Apr. 23, 2026

(54) PIXEL CIRCUIT AND ARRAY SUBSTRATE

(71) Applicant: Yungu (Gu’an) Technology Co., Ltd., Langfang (CN)

(72) Inventors: Lei MI, Langfang (CN); Jianjun LU, Langfang (CN); Cuili GAI, Langfang (CN); Yanan DING, Langfang (CN)

(73) Assignee: Yungu (Gu’an) Technology Co., Ltd., Langfang (CN)

(21) Appl. No.: 19/423,977

(22) Filed: Dec. 17, 2025

(30) Foreign Application Priority Data
Dec. 19, 2024 (CN) 202411885612.3

(51) Int. Cl. G09G 3/3233

(52) U.S. Cl. CPC G09G 3/3233; G09G 2300/043; G09G 2300/0819; G09G 2300/0842

(57) ABSTRACT

The pixel circuit includes: a drive sub-circuit, a first terminal of the drive sub-circuit being connected to a first power line, where in each drive cycle, a voltage of a first power signal on the first power line differs in at least two drive phases; and a threshold compensation sub-circuit, the threshold compensation sub-circuit being connected between a second terminal of the drive sub-circuit and a control terminal of the drive sub-circuit, and the threshold compensation sub-circuit being configured to reset the drive sub-circuit and perform threshold compensation on the drive sub-circuit in a time-division manner, where the first power signal includes a second reset voltage and a first power voltage.

### CROSS-REFERENCE TO RELATED APPLICATIONS

The present application claims priority to the Chinese Patent Application 202411885612.3, filed on Dec. 19, 2024, and the entire contents of the aforementioned application are hereby incorporated by reference in its entirety.

### FIELD

The present disclosure relates to the field of displays, and in particular to a pixel circuit and an array substrate.

### BACKGROUND

With the rapid development of display technology, display products having organic light-emitting diodes (OLEDs) are increasingly widely used.

However, the use performance of current OLED display panels needs to be improved.

### SUMMARY

The present disclosure provides a pixel circuit and an array substrate in order to improve the use performance of the display panel.

According to an aspect of the present disclosure, a pixel circuit is provided. The pixel circuit includes:
a drive sub-circuit, a first terminal of the drive sub-circuit being connected to a first power line, where in a same display frame, a voltage of a first power signal on the first power line differs in at least two drive phases; and
a threshold compensation sub-circuit, the threshold compensation sub-circuit being connected between a second terminal of the drive sub-circuit and a control terminal of the drive sub-circuit, and the threshold compensation sub-circuit being configured to reset the drive sub-circuit and perform threshold compensation on the drive sub-circuit in a time-division manner, where the first power signal includes a second reset voltage and a first power voltage, and the first power line is configured to transmit the second reset voltage and the first power voltage to the first terminal of the drive sub-circuit in a time-division manner.

According to another aspect of the present disclosure, an array substrate is provided. The array substrate includes:
a base substrate;
a first active layer located on a side of the base substrate, the first active layer including a first active region, and the first active region being provided with a channel region of a drive transistor and a channel region of a threshold compensation transistor;
a first conductive layer located on a side of the first active layer facing away from the base substrate, the first conductive layer including a first metal block forming a control electrode of the drive transistor and a third scan line forming a control electrode of the threshold compensation transistor, the third scan line extending in a first direction, the channel region of the drive transistor being located at an orthographic projection of the first metal block on the first active region, the channel region of the threshold compensation transistor being located at an orthographic projection of the third scan line on the first active region, the first metal block being connected to a first electrode of the threshold compensation transistor through a first connection portion, and a second electrode of the drive transistor being connected to a second electrode of the threshold compensation transistor through the first active region;
a second conductive layer located on a side of the first conductive layer facing away from the base substrate, the second conductive layer including a second metal block forming a second electrode of a coupling capacitor, the first metal block being reused as a first electrode of the coupling capacitor, and an orthographic projection of the second metal block on the base substrate covering an orthographic projection of the first metal block on the base substrate;
a second active layer located on a side of the second conductive layer facing away from the base substrate, the second active layer including a third active region, and the third active region being provided with a channel region of a data writing transistor; and
a fourth conductive layer located on a side of the second active layer facing away from the base substrate, the fourth conductive layer including a first scan line forming a control electrode of the data writing transistor, the first scan line extending in the first direction, the channel region of the data writing transistor being located at an orthographic projection of the first scan line on the third active region, and a second electrode of the data writing transistor being connected to the second metal block through a second connection portion, where
the first active layer and the second active layer are made of different materials.

It should be understood that the content described in this section is not intended to identify key or important features of embodiments of the present disclosure, and not intended to limit the scope of the present disclosure. Other features of the present disclosure will be easily understood through the following description.

### BRIEF DESCRIPTION OF THE DRAWINGS

In order to more clearly illustrate the embodiments of the present disclosure, the accompanying drawings used for describing the embodiments will be briefly described below. It is evident that, the accompanying drawings in the following description are only some embodiments of the present disclosure.

FIG. 1 is a schematic structural diagram of a pixel circuit according to an embodiment of the present disclosure;

FIG. 2 is a schematic structural diagram of another pixel circuit according to an embodiment of the present disclosure;

FIG. 3 is a schematic structural diagram of another pixel circuit according to an embodiment of the present disclosure;

FIG. 4 is a schematic structural diagram of another pixel circuit according to an embodiment of the present disclosure;

FIG. 5 is a schematic structural diagram of another pixel circuit according to an embodiment of the present disclosure;

FIG. 6 is a schematic structural diagram of a display panel corresponding to a pixel circuit according to an embodiment of the present disclosure;

FIG. 7 is a schematic structural diagram of another pixel circuit according to an embodiment of the present disclosure;

FIG. 8 is a schematic structural diagram of another pixel circuit according to an embodiment of the present disclosure;

FIG. 9 is a schematic structural diagram of another pixel circuit according to an embodiment of the present disclosure;

FIG. 10 is a schematic structural diagram of another pixel circuit according to an embodiment of the present disclosure;

FIG. 11 is a drive timing diagram of a pixel circuit according to an embodiment of the present disclosure;

FIG. 12 is a drive timing diagram of another pixel circuit according to an embodiment of the present disclosure;

FIG. 13 is a drive timing diagram of another pixel circuit according to an embodiment of the present disclosure;

FIG. 14 is a schematic structural top view of an array substrate according to an embodiment of the present disclosure;

FIG. 15 is a schematic view of a layout structure of a first active layer and a first conductive layer of an array substrate according to an embodiment of the present disclosure;

FIG. 16 is a schematic view of a layout structure of a second conductive layer and a third conductive layer of an array substrate according to an embodiment of the present disclosure;

FIG. 17 is a schematic view of a layout structure of a second active layer and a fourth conductive layer of an array substrate according to an embodiment of the present disclosure;

FIG. 18 is a schematic structural view of a first active layer, a first conductive layer, a second conductive layer, and a third conductive layer of an array substrate according to an embodiment of the present disclosure;

FIG. 19 is a schematic view of a layout structure of a second conductive layer, a third conductive layer, a second active layer, and a fourth conductive layer of an array substrate according to an embodiment of the present disclosure;

FIG. 20 is a schematic structural top view of another array substrate according to an embodiment of the present disclosure;

FIG. 21 is a sectional view of FIG. 14 taken along line a1-a2;

FIG. 22 is a schematic view of a layout structure of a first active layer, a first conductive layer, and a third active layer of an array substrate according to an embodiment of the present disclosure;

FIG. 23 is a sectional view of FIG. 18 taken along line b1-b2;

FIG. 24 is a sectional view of FIG. 18 taken along line e1-e2;

FIG. 25 is a sectional view of FIG. 19 taken along line f1-f2;

FIG. 26 is a schematic view of a layout structure of a third conductive layer, a second active layer, and a sixth insulation layer of an array substrate according to an embodiment of the present disclosure;

FIG. 27 is a schematic view of a layout structure of a fifth conductive layer of an array substrate according to an embodiment of the present disclosure;

FIG. 28 is a sectional view of FIG. 14 taken along line h1-h2;

FIG. 29 is a sectional view of FIG. 14 taken along line h3-h4;

FIG. 30 is a flowchart of a driving method for a pixel circuit according to an embodiment of the present disclosure; and

FIG. 31 is a schematic structural diagram of a display panel according to an embodiment of the present disclosure.

### DETAILED DESCRIPTION OF THE EMBODIMENTS

In order to better understand the embodiments of the present disclosure, the embodiments of the present disclosure will be clearly and completely described below with reference to the accompanying drawings for the embodiments of the present disclosure. It is evident that, the described embodiments are merely some of, rather than all of, the embodiments of the present disclosure.

It should be noted that, in the description, claims, and accompanying drawings of the present disclosure, the terms such as “first” and “second” are used for distinguishing similar objects, but are not necessarily used for describing a specific sequence or order. It should be understood that the data termed in such a way is interchangeable in proper circumstances the embodiments of the present disclosure described herein can be implemented in an order other than the order illustrated or described herein. In addition, the terms “include” and “have” and any variation thereof are intended to cover a non-exclusive inclusion, for example, a process, method, system, product, or device that includes a series of steps or units is not necessarily limited to those steps or units that are explicitly listed, but may include other steps or units not explicitly listed or inherent to such processes, methods, products or devices.

As mentioned in the background, existing display panels face a problem that the use performance needs to be improved. The inventors have found through research that the cause of this problem is as follows: With the development of display technology and thus the increasingly wide application of display panels, limitations in array processes and film layer structures hinder the display panels from achieving a high pixel density (pixels per inch, PPI). Consequently, the display panels cannot display images at higher densities, and a lower display density indicates a lower image fidelity, which stops display devices from achieving high image fidelity, results in poor display effects of the display devices and affects the use performance of the display devices. A display panel of a display device includes a plurality of pixel circuits and light-emitting elements, where the pixel circuits can generate drive currents to drive the light-emitting elements to emit light. In order to achieve a high pixel density, in the related art, a number of transistors used in a pixel circuit is reduced. For example, the pixel circuit is a 2TIC pixel circuit. However, reducing the number of transistors reduces the functionality of the pixel circuit. For example, the pixel circuit may become unable to perform functions such as initialization or threshold compensation. This causes residual charges and threshold drift to induce changes in a drive current, resulting in a significant difference between a luminous brightness of a light-emitting element and a target brightness. Consequently, the image display effect of the display panel is poor, which affects the use performance of the display panel.

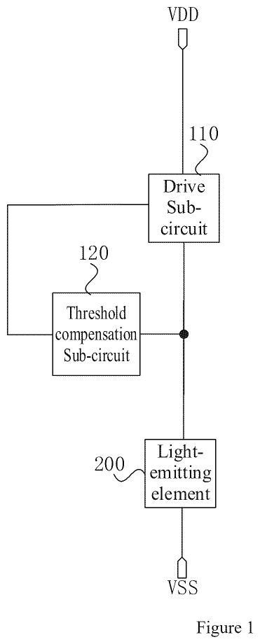

In view of the above problems, an embodiment of the present disclosure provides a pixel circuit. FIG. 1 is a schematic structural diagram of a pixel circuit according to an embodiment of the present disclosure. Referring to FIG. 1, the pixel circuit includes: a drive sub-circuit 110, a first terminal of the drive sub-circuit 110 being connected to a first power line VDD, where in each drive cycle, a voltage of a first power signal on the first power line VDD differs in at least two drive phases; and
a threshold compensation sub-circuit 120, the threshold compensation sub-circuit 120 being connected between a second terminal of the drive sub-circuit 110 and a control terminal of the drive sub-circuit, and the threshold compensation sub-circuit 120 being configured to reset the drive sub-circuit 110 and perform threshold compensation on the drive sub-circuit in a time-division manner, where the first power signal includes a second reset voltage and a first power voltage, and the first power line VDD is configured to transmit the second reset voltage and the first power voltage to the first terminal of the drive sub-circuit 110 in a time-division manner.

Here, one drive cycle of the pixel circuit is one display frame of a display panel. One drive cycle of the pixel circuit includes a plurality of drive phases, such as a reset phase, a data writing phase, a compensation phase, and a light emission phase, which are not limited here. The pixel circuit may be connected to a light-emitting element 200 to drive the corresponding light-emitting element 200 to emit light. For example, the second terminal of the drive sub-circuit 110 is connected to a first terminal of the light-emitting element 200, and a second terminal of the light-emitting element 200 is connected to a second power line VSS. The drive sub-circuit 110 may generate a drive current and the light-emitting element 200 may emit light in response to the drive current. Here, the first power signal includes the first power voltage. For example, the first power voltage is a positive voltage, and a second power voltage on the second power line VSS is a negative voltage or zero; or the first power voltage is a negative voltage or zero, and the second power voltage on the second power line VSS is a positive voltage, which is not limited in this embodiment.
the first power line VDD may transmit the first power signal. The voltage of the first power signal is set to differ in the at least two drive phases, the first power line VDD may transmit different voltages in a time-division manner. The first power signal includes the second reset voltage and the first power voltage, the second reset voltage being less than the first power voltage. When the first power signal is at the second reset voltage, the second reset voltage is transmitted to the control terminal of the drive sub-circuit 110 through the drive sub-circuit 110 and the threshold compensation sub-circuit 120, to reset the control terminal of the drive sub-circuit 110, that is, the threshold compensation sub-circuit 120 resets the drive sub-circuit 110. When the first power signal is at the first power voltage, the first power voltage charges the control terminal of the drive sub-circuit 110 through the drive sub-circuit 110 and the threshold compensation sub-circuit 120, and a voltage at the control terminal of the drive sub-circuit 110 is a voltage related to both the first power voltage and a threshold voltage of a transistor in the drive sub-circuit 110, thereby implementing threshold compensation on the drive sub-circuit 110, that is, the threshold compensation sub-circuit 120 performs threshold compensation on the drive sub-circuit 110. In this way, the threshold compensation sub-circuit 120 resets the drive sub-circuit 110 and performs threshold compensation on the drive sub-circuit in a time-division manner. As a result, there is no need to provide a large number of sub-circuits to achieve compensation and reset, which reduces a number of transistors and is conducive to increasing the pixel density of the display panel corresponding to the pixel circuit. Therefore, it is ensured that reset and compensation can be performed on the pixel circuit with fewer components in the pixel circuit. This means that the normal operation of the pixel circuit is ensured while maintaining a high pixel density of the display panel, thereby improving the use performance of the display panel.

In addition, the second reset voltage may be transmitted to the first terminal of the light-emitting element 200 through the drive sub-circuit 110, to reset the light-emitting element 200. There is no need to separately provide a corresponding reset component for the light-emitting element 200, thereby further increasing the pixel density of the display panel corresponding to the pixel circuit. Moreover, when the first power signal is at the first power voltage, a current path may be formed by the first power voltage, the drive sub-circuit 110, the light-emitting element 200, and the second power voltage, enabling the drive sub-circuit 110 to generate a drive current and the light-emitting element 200 may emit light in response to the drive current.

According to the embodiments, the voltage of the first power signal is set to differ in the at least two drive phases, the first power line may transmit different voltages in a time-division manner. When the first power signal is at the second reset voltage, the second reset voltage is transmitted to the control terminal of the drive sub-circuit through the drive sub-circuit and the threshold compensation sub-circuit, the threshold compensation sub-circuit resets the drive sub-circuit. When the first power signal is at the first power voltage, the voltage at the control terminal of the drive sub-circuit may be the voltage related to both the first power voltage and the threshold voltage of the transistor in the drive sub-circuit, the threshold compensation sub-circuit performs threshold compensation on the drive sub-circuit. In this way, the threshold compensation sub-circuit resets the drive sub-circuit and performs threshold compensation on the drive sub-circuit in a time-division manner. As a result, there is no need to provide a large number of sub-circuits to achieve compensation and reset, which reduces a number of transistors and is conducive to increasing the pixel density of the display panel corresponding to the pixel circuit. Therefore, the normal operation of the pixel circuit is ensured while maintaining a high pixel density of the display panel, thereby improving the use performance of the display panel.

On the basis of the above-mentioned embodiment, in the reset phase of the same display frame, the first power signal is at the second reset voltage, and in remaining phases of the same display frame, the first power signal is at the first power voltage.

One drive cycle of the pixel circuit refers to a time period from the end of light emission of the light-emitting element of the pixel circuit in a previous frame to the end of light emission of the light-emitting element in a current frame, which specifically includes the reset phase, and may further include the compensation phase, the data writing phase, the light emission phase, etc. With the configuration that in the reset phase, the first power signal is at the second reset voltage, and the second reset voltage is transmitted to the control terminal of the drive sub-circuit 110 through the drive sub-circuit 110 and the threshold compensation sub-circuit 120, the control terminal of the drive sub-circuit 110 is reset in the reset phase. In the remaining phases, the first power signal is at the first power voltage, the threshold compensation sub-circuit 120 performs threshold compensation on the drive sub-circuit 110 using the first power voltage, and therefore the first power voltage, the drive sub-circuit 110, the light-emitting element 200, and the second power voltage form the current path. In this way, the drive sub-circuit 110 may generate the drive current.

On the basis of the above-mentioned embodiments, the voltage of the first power signal jumps from the first power voltage to the second reset voltage in a first sub-phase of the reset phase. In this way, at the beginning of the reset phase, the first power signal changes to the second reset voltage, the drive sub-circuit 110 is reset based on the second reset voltage and the impact of a light emission voltage of the previous frame on the drive sub-circuit 110 is eliminated.

The threshold compensation sub-circuit 120 is configured to transmit the second reset voltage to the control terminal of the drive sub-circuit 110 in a second sub-phase of the reset phase, to reset the control terminal of the drive sub-circuit 110.

The second sub-phase is later than the first sub-phase. After the first power signal changes to the second reset voltage, the threshold compensation sub-circuit 120 transmits the second reset voltage to the control terminal of the drive sub-circuit 110 in the second sub-phase of the reset phase, that is, the second reset voltage is transmitted to the control terminal of the drive sub-circuit 110 through the drive sub-circuit 110 and the threshold compensation sub-circuit 120, which can clear residual voltages at the first terminal and the control terminal of the drive sub-circuit 110, thereby resetting the drive sub-circuit 110.

The threshold compensation sub-circuit 120 is further configured to perform threshold compensation on the drive sub-circuit 110 in the threshold compensation phase, where the voltage of the first power signal jumps from the second reset voltage to the first power voltage in the threshold compensation phase.
in the threshold compensation phase, the voltage of the first power signal jumps from the second reset voltage to the first power voltage, and the first power voltage charges the control terminal of the drive sub-circuit 110 through the drive sub-circuit 110 and the threshold compensation sub-circuit 120, and the voltage at the control terminal of the drive sub-circuit 110 is the voltage related to both the first power voltage and the threshold voltage of the transistor in the drive sub-circuit 110, thereby implementing threshold compensation on the drive sub-circuit 110, that is, the threshold compensation sub-circuit 120 performs threshold compensation on the drive sub-circuit 110.

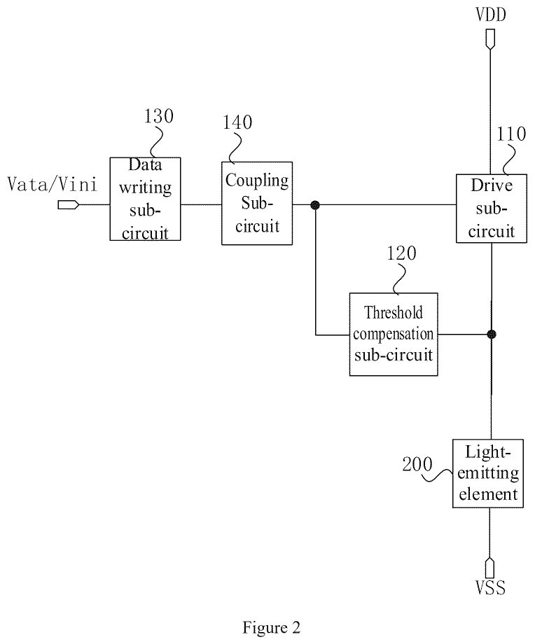

On the basis of the above-mentioned embodiments, FIG. 2 is a schematic structural diagram of another pixel circuit according to an embodiment of the present disclosure. referring to FIG. 2, the pixel circuit further includes a data writing sub-circuit 130 and a coupling sub-circuit 140, where a first terminal of the data writing sub-circuit 130 is connected to a data voltage Vdata or a first reset voltage Vini, the coupling sub-circuit 140 is connected between a second terminal of the data writing sub-circuit 130 and the control terminal of the drive sub-circuit 110, and the data writing sub-circuit 130 is configured to transmit the data voltage Vdata and the first reset voltage Vini to the coupling sub-circuit 140 in a time-division manner.

For example, a first terminal of the coupling sub-circuit 140 is connected to the control terminal of the drive sub-circuit 110, and a second terminal of the coupling sub-circuit 140 is connected to the second terminal of the data writing sub-circuit 130.

The first terminal of the data writing sub-circuit 130 may be connected to the data voltage Vdata and the first reset voltage Vini in a time-division manner, the data writing sub-circuit 130 may transmit the data voltage Vdata and the first reset voltage Vini to the second terminal of coupling sub-circuit 140 in a time-division manner. The coupling sub-circuit 140 may couple the first reset voltage Vini and the data voltage Vdata to the control terminal of the drive sub-circuit 110 in a time-division manner, to implement the reset of and data writing to the control terminal of the drive sub-circuit 110. In the reset phase, for example, the data writing sub-circuit 130 transmits the first reset voltage Vini to the second terminal of the coupling sub-circuit 140, and the coupling sub-circuit 140 couples the first reset voltage Vini to the control terminal of the drive sub-circuit 110, to reset the drive sub-circuit 110. In the data writing phase, the data writing sub-circuit 130 transmits the data voltage Vdata to the second terminal of the coupling sub-circuit 140, and the coupling sub-circuit 140 couples the data voltage Vdata to the control terminal of the drive sub-circuit 110, in the light emission phase, the drive sub-circuit 110 may generate the drive current based on the data voltage Vdata and the light-emitting element 200 may emit light in response to the drive current.

The data writing sub-circuit 130 is configured to transmit the first reset voltage Vini to the coupling sub-circuit 140 in a third sub-phase of the reset phase, to reset the control terminal of the drive sub-circuit 110 through the coupling sub-circuit 140. In this way, with the coupling effect of the coupling sub-circuit 140, the control terminal of the drive sub-circuit 110 may be reset in the reset phase, to implement the control of a potential at the control terminal of the drive sub-circuit 110.

The third sub-phase is later than the second sub-phase.

In the second sub-phase, after the threshold compensation sub-circuit 120 resets the control terminal of the drive sub-circuit 110, the first terminal and the control terminal of the drive sub-circuit 110 are at the second reset voltage. With the configuration that the third sub-phase is later than the second sub-phase, and the data writing sub-circuit 130 transmits the first reset voltage Vini to the coupling sub-circuit 140 in the third sub-phase of the reset phase, for example, if the drive sub-circuit 110 needs to be reset at a low voltage, and the first reset voltage Vini is greater than the second reset voltage, in the third sub-phase and with the coupling effect of the coupling sub-circuit 140, the voltage at the control terminal of the drive sub-circuit 110 is slightly pulled up but still remains at a low voltage, to reset the control terminal of the drive sub-circuit 110. For example, if the drive sub-circuit 110 needs to be reset at a high voltage, and the first reset voltage Vini is less than the second reset voltage, in the third sub-phase and with the coupling effect of the coupling sub-circuit 140, the voltage at the control terminal of the drive sub-circuit 110 is slightly pulled down but still remains at a high voltage, to reset the control terminal of the drive sub-circuit 110.

In one reset phase, a duration of the second sub-phase is greater than a duration of the third sub-phase. In this way, a time period for resetting the drive sub-circuit 110 using the second reset voltage is longer, which makes the potential at the control terminal of the drive sub-circuit 110 closer to the second reset voltage, thereby achieving a better reset effect of the control terminal of the drive sub-circuit 110.

In one reset phase, the duration of the second sub-phase is greater than a duration of the first sub-phase. Here, the first sub-phase is mainly a voltage jump phase with a short duration, while the second sub-phase has a longer duration, which allows the second reset voltage to be more fully written to the control terminal of the drive sub-circuit 110, the potential at the control terminal of the drive sub-circuit 110 is closer to the second reset voltage, thereby achieving a better reset effect of the control terminal of the drive sub-circuit 110.

On the basis of the above-mentioned embodiment, a possible structure of the data writing sub-circuit 130 will be described below. However, this is not intended to limit the present application.

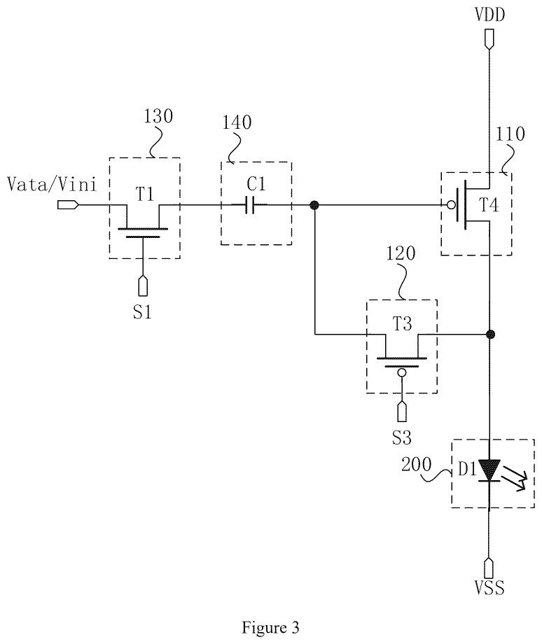

In one embodiment, FIG. 3 is a schematic structural diagram of another pixel circuit according to an embodiment of the present disclosure. referring to FIG. 3, the data writing sub-circuit 130 includes a data writing transistor T1, a first electrode of the data writing transistor T1 being connected to the data voltage Vdata or the first reset voltage Vini, a second electrode of the data writing transistor T1 being connected to the coupling sub-circuit 140, and a control electrode of the data writing transistor T1 being connected to a first scan line S1; and the data writing transistor T1 being configured to transmit the data voltage Vdata and the first reset voltage Vini to the coupling sub-circuit 140 in a time-division manner.

The data writing transistor T1 may transmit the data voltage Vdata and the first reset voltage Vini to the second terminal of the coupling sub-circuit 140 in a time-division manner based on a first scan signal of the first scan line S1. The coupling sub-circuit 140 may couple the first reset voltage Vini and the data voltage Vdata to the control terminal of the drive sub-circuit 110 in a time-division manner, to implement the reset of and data writing to the control terminal of the drive sub-circuit 110. The data writing transistor T1 may be either an N-type transistor or a P-type transistor. FIG. 3 shows a case in which the data writing transistor T1 is an N-type transistor, but this is not intended to be limiting.

Referring to FIG. 3, the data writing transistor T1 is configured to transmit the data voltage Vdata to the coupling sub-circuit 140 in the data writing phase, and transmit the first reset voltage Vini to the coupling sub-circuit 140 in at least part of the time period of the reset phase.

In the data writing phase, the data writing transistor T1 transmits the data voltage Vdata to the second terminal of the coupling sub-circuit 140, and the coupling sub-circuit 140 couples the data voltage Vdata to the control terminal of the drive sub-circuit 110, in the light emission phase, the drive sub-circuit 110 may generate the drive current based on the data voltage Vdata and the light-emitting element 200 may emit light in response to the drive current.

In at least part of the time period of the reset phase, the data writing transistor T1 transmits the first reset voltage Vini to the coupling sub-circuit 140, for example, to the second terminal of the coupling sub-circuit 140, the second terminal of the coupling sub-circuit 140 may be reset. In addition, the coupling sub-circuit 140 may couple the first reset voltage Vini to the control terminal of the drive sub-circuit 110, to reset the drive sub-circuit 110.

Referring to FIG. 3, the data writing transistor T1 is configured to transmit the first reset voltage Vini to the coupling sub-circuit 140 in the third sub-phase of the reset phase.

In the second sub-phase, after the threshold compensation sub-circuit 120 resets the control terminal of the drive sub-circuit 110, the control terminal of the drive sub-circuit 110 is at the second reset voltage. The data writing transistor T1 transmits the first reset voltage Vini to the coupling sub-circuit 140 in the third sub-phase of the reset phase. For example, if the drive sub-circuit 110 needs to be reset at a low voltage, and the first reset voltage Vini is greater than the second reset voltage, in the third sub-phase and with the coupling effect of the coupling sub-circuit 140, the voltage at the control terminal of the drive sub-circuit 110 is slightly pulled up but still remains at a low voltage, to reset the control terminal of the drive sub-circuit 110.

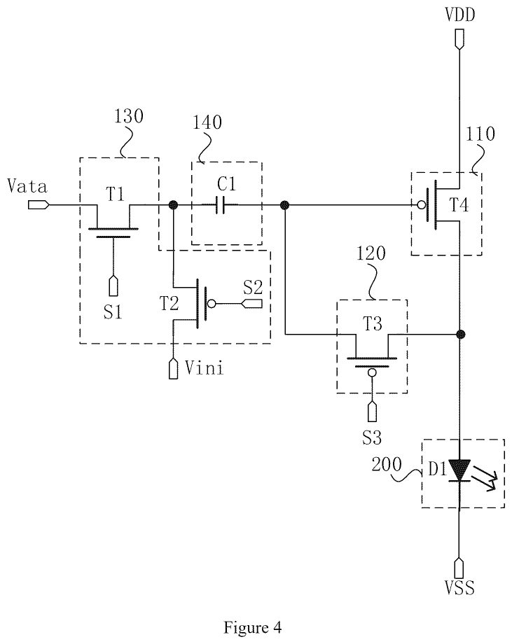

In another embodiment, FIG. 4 is a schematic structural diagram of another pixel circuit according to an embodiment of the present disclosure. referring to FIG. 4, the data writing sub-circuit 130 includes a data writing transistor T1 and a reset transistor T2, where
a control electrode of the data writing transistor T1 is connected to a first scan line S1, a first electrode of the data writing transistor T1 is connected to the data voltage Vdata, a second electrode of the data writing transistor T1 is connected to the coupling sub-circuit 140, the data writing transistor T1 is configured to transmit the data voltage Vdata to the coupling sub-circuit 140 in a data writing phase, and the coupling sub-circuit 140 is configured to couple the data voltage Vdata to the control terminal of the drive sub-circuit 110; and
a first electrode of the reset transistor T2 is connected to the first reset voltage Vini, a second electrode of the reset transistor T2 is connected to the coupling sub-circuit 140, and the reset transistor T2 is configured to transmit the first reset voltage Vini to the coupling sub-circuit 140 in at least part of the time period of the reset phase.

In at least part of the time period of the reset phase, the reset transistor T2 is turned on, and transmits the first reset voltage Vini to the coupling sub-circuit 140, for example, to the second terminal of the coupling sub-circuit 140, the second terminal of the coupling sub-circuit 140 may be reset. In addition, the coupling sub-circuit 140 may couple the first reset voltage Vini to the control terminal of the drive sub-circuit 110, to reset the drive sub-circuit 110.

In the data writing phase, the first scan signal on the first scan line S1 controls the data writing transistor T1 to turn on, the data writing transistor T1 transmits the data voltage Vdata to the second terminal of the coupling sub-circuit 140, and the coupling sub-circuit 140 couples the data voltage Vdata to the control terminal of the drive sub-circuit 110, in the light emission phase, the drive sub-circuit 110 may generate the drive current based on the data voltage Vdata and the light-emitting element 200 may emit light in response to the drive current.

Referring to FIG. 4, the reset transistor T2 is configured to transmit the first reset voltage Vini to the coupling sub-circuit 140 in the third sub-phase of the reset phase.

In the second sub-phase, after the threshold compensation sub-circuit 120 resets the control terminal of the drive sub-circuit 110, the control terminal of the drive sub-circuit 110 is at the second reset voltage. In the third sub-phase of the reset phase, the reset transistor T2 transmits the first reset voltage Vini to the coupling sub-circuit 140. For example, if the drive sub-circuit 110 needs to be reset at a low voltage, and the first reset voltage Vini is greater than the second reset voltage, in the third sub-phase and with the coupling effect of the coupling sub-circuit 140, the voltage at the control terminal of the drive sub-circuit 110 is slightly pulled up but still remains at a low voltage, to reset the control terminal of the drive sub-circuit 110.

On the basis of the above-mentioned embodiment, referring to FIG. 4, a control electrode of the reset transistor T2 is connected to a second scan line S2. Thus, the reset transistor T2 may be turned on or off based on a second scan signal on the second scan line S2, when the reset transistor T2 is turned on in response to the second scan signal, the second terminal of the coupling sub-circuit 140 and the control terminal of the drive sub-circuit 110 may be reset.

Referring to FIG. 4, the threshold compensation sub-circuit 120 includes a threshold compensation transistor T3, a control electrode of the threshold compensation transistor T3 being connected to a third scan line S3, and the threshold compensation transistor T3 being connected between the second terminal of the drive sub-circuit 110 and the control terminal of the drive sub-circuit 110.

When the first power signal is at the second reset voltage, a third scan signal on the third scan line S3 controls the threshold compensation transistor T3 to turn on, and the second reset voltage is transmitted to the control terminal of the drive sub-circuit 110 through the drive sub-circuit 110 and the threshold compensation transistor T3, to reset the control terminal of the drive sub-circuit 110, that is, the threshold compensation transistor T3 resets the drive sub-circuit 110. When the first power signal is at the first power voltage, the third scan signal on the third scan line S3 controls the threshold compensation transistor T3 to turn on, and the first power voltage charges the control terminal of the drive sub-circuit 110 through the drive sub-circuit 110 and the threshold compensation transistor T3, the voltage at the control terminal of the drive sub-circuit 110 is the voltage related to both the first power voltage and the threshold voltage of the transistor in the drive sub-circuit 110, thereby implementing threshold compensation on the drive sub-circuit 110, that is, the threshold compensation transistor T3 performs threshold compensation on the drive sub-circuit 110. In this way, the threshold compensation transistor T3 resets the drive sub-circuit 110 and performs threshold compensation on the drive sub-circuit in a time-division manner.

Referring to FIG. 4, a type of the threshold compensation transistor T3 is the same as that of the reset transistor T2.

The display panel corresponding to the pixel circuit includes a shift register. The shift register includes a plurality of cascaded gate driving circuits, and the gate driving circuits can provide scan signals to the pixel circuit. With the configuration that the type of the threshold compensation transistor T3 is the same as that of the reset transistor T2, the second scan line S2 and the third scan line S3 may be connected to a same shift register, for example, to gate driving circuits of different stages in the same shift register. This can reduce the number of shift registers, which is conducive to reducing the bezel size.

In one embodiment, referring to FIG. 4, the threshold compensation transistor T3 and the reset transistor T2 are both P-type transistors. Thus, when the third scan signal is at a low level, the threshold compensation transistor T3 is turned on, and then the third scan signal may pull down the control terminal of the drive sub-circuit 110 through coupling, thereby achieving a better reset effect of the control terminal of the drive sub-circuit 110. Moreover, this makes the threshold compensation transistor T3 and the reset transistor T2 smaller in size, which is conducive to increasing the pixel density of the display panel.

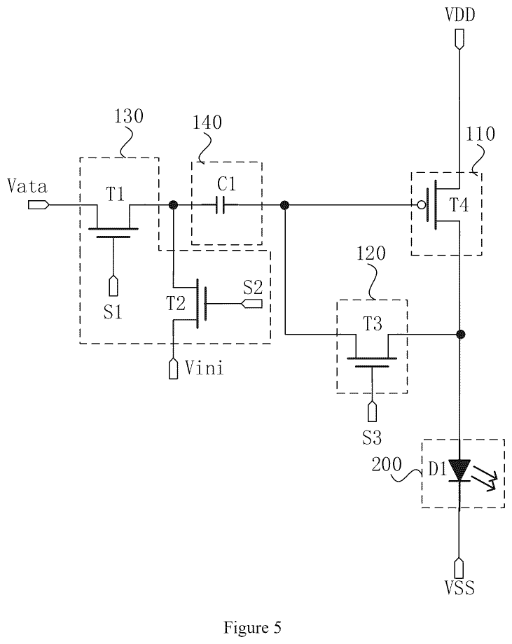

In another embodiment, FIG. 5 is a schematic structural diagram of another pixel circuit according to an embodiment of the present disclosure. referring to FIG. 5, the threshold compensation transistor T3 and the reset transistor T2 are both N-type transistors. In this way, a leakage current at the control terminal of the drive sub-circuit 110 may be reduced, thereby avoiding a fluctuation in the drive current generated by the drive sub-circuit 110. As a result, the light-emitting element 200 may emit light stably, thereby improving the display quality of the display panel.

Referring to FIG. 4, a start time of an effective level of the second scan signal on the second scan line S2 is delayed by one row time relative to a start time of an effective level of the third scan signal on the third scan line S3; and cycles of the second scan signal and the third scan signal are the same, and waveforms of the second scan signal and the third scan signal are the same. Thus, the second scan signal and the third scan signal may be provided by gate driving circuits of different stages in the same shift register. For example, a gate driving circuit of an m^{th} stage outputs a third scan signal corresponding to an m^{th} row of pixel circuits; and a gate driving circuit of an (m+1)th stage outputs a third scan signal corresponding to an (m+1)th row of pixel circuits, which also serves as a second scan signal corresponding to the m^{th} row of pixel circuits. This allows the second scan line S2 and the third scan line S3 to be connected to the same shift register, thereby reducing the number of shift registers, which is conducive to reducing the bezel size. Here, m is a positive integer.

Here, one row time is a time interval between start times of effective levels of third scan signals S3 corresponding to two adjacent rows of pixel circuits. One row time may be calculated based on the resolution and refresh rate of the display panel. The number of rows of pixel circuits (i.e., the number of rows of light-emitting elements) may be determined based on the resolution, and then one row time is

$$\frac{1}{refresh rate * number of rows of pixel circuits} .$$

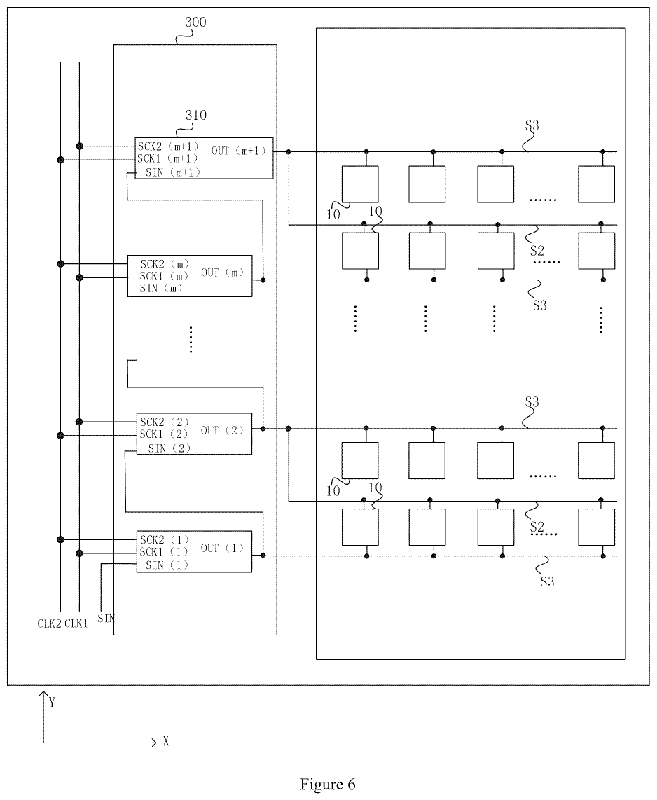

FIG. 6 is a schematic structural diagram of a display panel corresponding to a pixel circuit according to an embodiment of the present disclosure. referring to FIG. 6, the second scan line S2 and the third scan line S3 extend in a first direction X, and among two pixel circuits 10 adjacent in a second direction Y, a third scan line S3 corresponding to one pixel circuit 10 is connected to a second scan line S2 corresponding to the other pixel circuit 10, the first direction X intersecting the second direction Y.

As shown in FIG. 6, the display panel corresponding to the pixel circuit includes a shift register 300, the shift register 300 including a plurality of cascaded gate driving circuits 310, where an input terminal of a gate driving circuit 310 of the first stage is connected to an input voltage SIN, and an input terminal of a gate driving circuit 310 of an (m+1)^{th} stage is connected to an output terminal of a gate driving circuit 310 of an m^{th} stage. A first clock terminal SCK1 of the gate driving circuit 310 of the m^{th} stage is connected to a first clock signal CLK1, a second clock terminal SCK2 of the gate driving circuit 310 of the m^{th} stage is connected to a second clock signal CLK2, a first clock terminal SCK1 of the gate driving circuit 310 of the (m+1)^{th} stage is connected to the second clock signal CLK2, and a second clock terminal SCK2 of the gate driving circuit 310 of the (m+1)^{th} stage is connected to the first clock signal CLK1.

An output terminal OUT (m+1) of the gate driving circuit of the (m+1)^{th} stage is connected to a third scan line S3 corresponding to the (m+1)^{th} row of pixel circuits 10, and is also connected to a second scan line S2 corresponding to the m^{th} row of pixel circuits. This allows the second scan line S2 and the third scan line S3 to be connected to the same shift register, thereby reducing the number of shift registers, which is conducive to reducing the bezel size.

On the basis of the above-mentioned embodiment, the second reset voltage is less than the first reset voltage Vini.

In the second sub-phase, after the threshold compensation sub-circuit 120 resets the control terminal of the drive sub-circuit 110, the control terminal of the drive sub-circuit 110 is at the second reset voltage. In the third sub-phase and with the coupling effect of the coupling sub-circuit 140, the voltage at the control terminal of the drive sub-circuit 110 is slightly pulled up but still remains at a low voltage, to reset the control terminal of the drive sub-circuit 110.

Referring to FIG. 3, 4, or 5, the light-emitting element 200 includes an organic light-emitting diode D1, where a first electrode of the organic light-emitting diode D1 serves as the first terminal of the light-emitting element 200, and a second electrode of the organic light-emitting diode D1 serves as the second terminal of the light-emitting element 200. Here, the first electrode of the organic light-emitting diode D1 is an anode, and the second electrode of the organic light-emitting diode D1 is a cathode; or the first electrode of the organic light-emitting diode D1 is a cathode, and the second electrode of the organic light-emitting diode D1 is an anode.

Referring to FIG. 3, 4, or 5, the drive sub-circuit 110 includes a drive transistor T4, a control electrode of the drive transistor T4 being connected to the coupling sub-circuit 140, a first electrode of the drive transistor T4 being connected to the first power signal, and a second electrode of the drive transistor T4 being connected to the threshold compensation sub-circuit 120.

When the first power signal is at the second reset voltage, the threshold compensation sub-circuit 120 transmits the second reset voltage to the control electrode of the drive transistor T4, to reset the control electrode of the drive transistor T4. When the first power signal is at the first power voltage, the threshold compensation sub-circuit 120 transmits a voltage related to both the first power voltage and a threshold voltage of the drive transistor T4 to the control electrode of the drive transistor T4, to perform threshold compensation on the drive transistor T4.

Referring to FIG. 3, 4, or 5, the coupling sub-circuit 140 includes a coupling capacitor C1, a first electrode of the coupling capacitor C1 being connected to the control electrode of the drive transistor T4, and a second electrode of the coupling capacitor C1 being connected to the data writing sub-circuit 130.

When the data writing sub-circuit 130 transmits the first reset voltage Vini to the second electrode of the coupling capacitor C1, the coupling capacitor C1 couples the first reset voltage Vini to the control electrode of the drive transistor T4, to reset the drive transistor T4. When the data writing sub-circuit 130 transmits the data voltage Vdata to the second electrode of the coupling capacitor C1, the coupling capacitor C1 couples the data voltage Vdata to the control electrode of the drive transistor T4, and the drive transistor T4 may generate a drive current based on the data voltage Vdata.

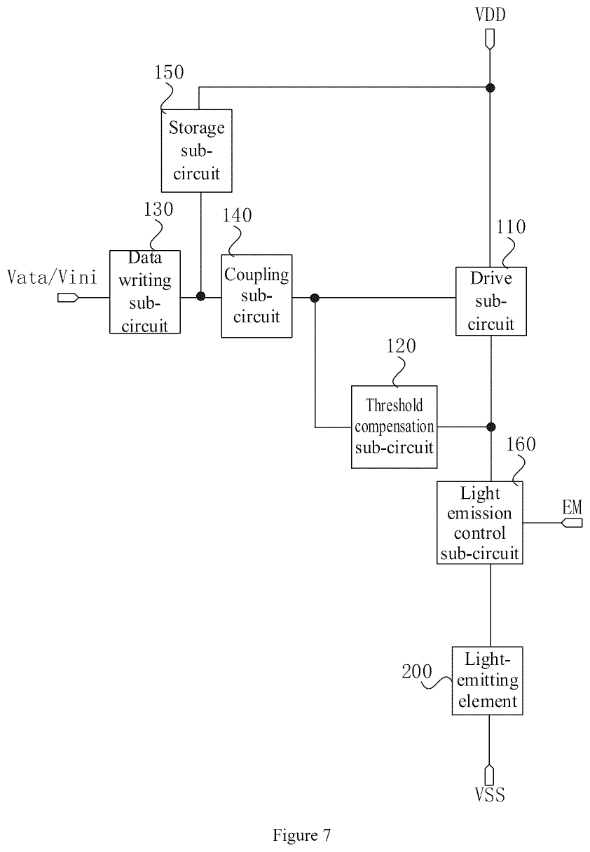

On the basis of the above-mentioned embodiments, FIG. 7 is a schematic structural diagram of another pixel circuit according to an embodiment of the present disclosure. referring to FIG. 7, the pixel circuit further includes a storage sub-circuit 150, where
a first terminal of the storage sub-circuit 150 is connected to the first power signal, and a second terminal of the storage sub-circuit 150 is connected to a second terminal of the coupling sub-circuit 140 or to the control terminal of the drive sub-circuit 110; and
a first terminal of the coupling sub-circuit 140 is connected to the control terminal of the drive sub-circuit 110.

The second terminal of the storage sub-circuit 150 is connected to the second terminal of the coupling sub-circuit 140, and a potential at the second terminal of the coupling sub-circuit 140 may be maintained, thereby maintaining the potential at the control terminal of the drive sub-circuit 110. The second terminal of the storage sub-circuit 150 is connected to the control terminal of the drive sub-circuit 110, and the potential at the control terminal of the drive sub-circuit 110 may be maintained. In this way, the potential at the control terminal of the drive sub-circuit 110 may be stable, and the drive sub-circuit 110 may generate a stable drive current, the light-emitting element 200 may emit light stably.

It should be noted that, FIG. 7 shows a case in which the second terminal of the storage sub-circuit 150 is connected to the second terminal of the coupling sub-circuit 140, but this is not intended to be limiting.

Referring to FIG. 7, the pixel circuit further includes a light emission control sub-circuit 160, a control terminal of the light emission control sub-circuit 160 being connected to a light emission control line EM, and the light emission control sub-circuit 160 being connected between the second terminal of the drive sub-circuit 110 and the light-emitting element 200.

The light emission control sub-circuit 160 may control whether the drive current generated by the drive sub-circuit 110 is transmitted to the light-emitting element 200, thereby controlling whether the light-emitting element 200 emits light. When a light emission control signal on the light emission control line EM is at an effective level, the light emission control sub-circuit 160 is turned on. This allows the first power line VDD, the drive sub-circuit 110, the light emission control sub-circuit 160, the light-emitting element 200, and the second power line VSS to form a current path, the drive sub-circuit 110 generates a drive current, and the light-emitting element 200 emits light in response to the drive current.

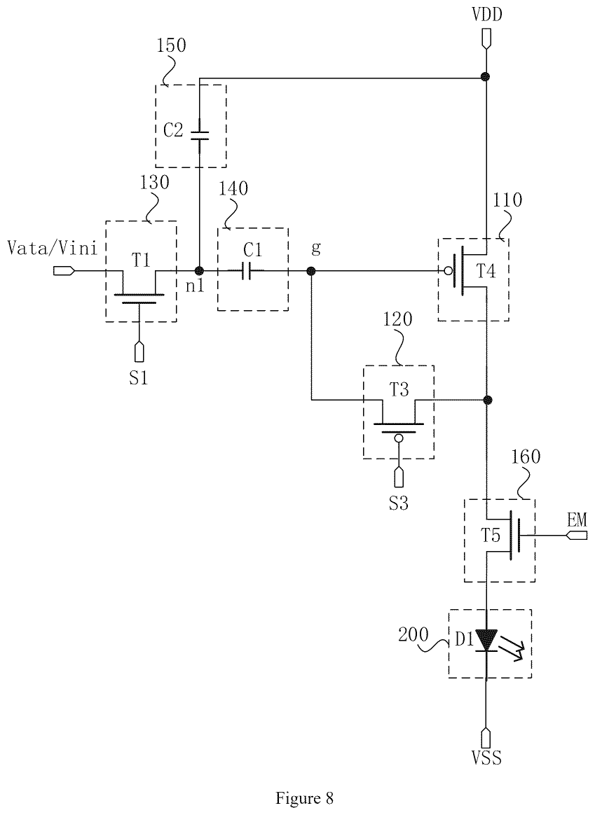

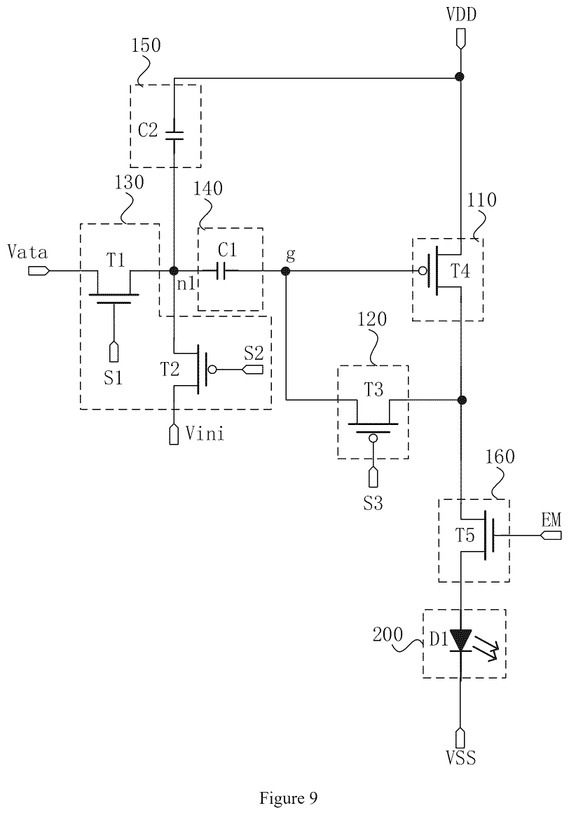

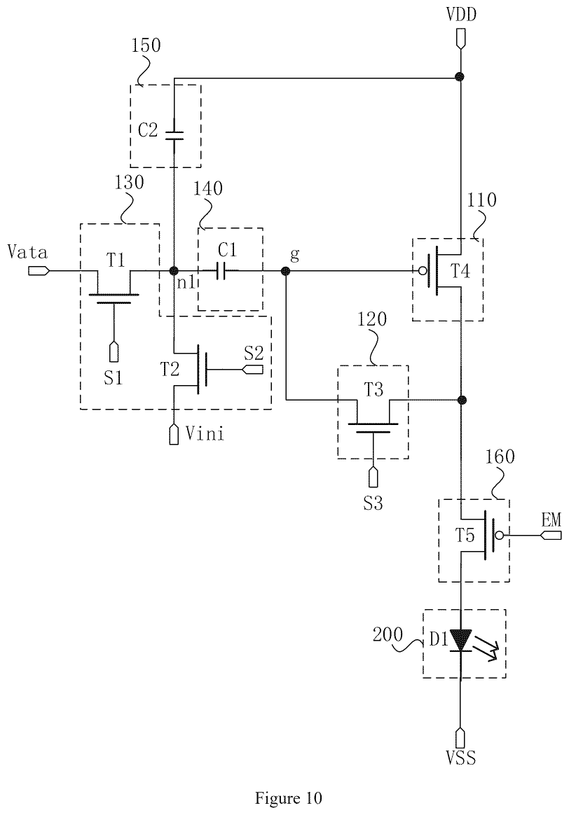

FIG. 8 is a schematic structural diagram of another pixel circuit according to an embodiment of the present disclosure, FIG. 9 is a schematic structural diagram of another pixel circuit according to an embodiment of the present disclosure, and FIG. 10 is a schematic structural diagram of another pixel circuit according to an embodiment of the present disclosure. referring to FIG. 8, 9, or 10, the storage sub-circuit 150 includes a storage capacitor C2, a first electrode of the storage capacitor C2 being connected to the first power signal, and a second electrode of the storage capacitor C2 being connected to the second terminal of the coupling sub-circuit 140. In this way, the storage capacitor C2 may maintain the voltage at the second terminal of the coupling sub-circuit 140, thereby maintaining a potential at the control electrode of the drive transistor T4, the drive transistor T4 may generate a stable drive current.

Referring to FIG. 8, 9, or 10, the light emission control sub-circuit 160 includes a light emission control transistor T5, a control electrode of the light emission control transistor T5 being connected to the light emission control line EM, and the light emission control transistor T5 being connected between the second terminal of the drive sub-circuit 110 and the light-emitting element 200. In this way, the light emission control transistor T5 may control whether the drive current generated by the drive transistor T4 is transmitted to the light-emitting element 200, thereby controlling whether the light-emitting element 200 emits light. As shown in FIGS. 8 and 9, the light emission control transistor T5 may be an N-type transistor. As shown in FIG. 10, the light emission control transistor T5 may be a P-type transistor. This embodiment does not limit the type of the light emission control transistor T5.

On the basis of the above-mentioned embodiments, the drive sub-circuit 110 includes the drive transistor T4, an active layer of the drive transistor T4 and an active layer of the data writing transistor T1 being made of different materials. That is, the drive transistor T4 is of a different type from the data writing transistor T1, the active layer of the drive transistor T4 and the active layer of the data writing transistor T1 are stacked, meaning transistors of different types being stacked. This reduces an area occupied by the pixel circuit, thereby increasing the pixel density of the display panel.

Referring to FIG. 8, 9, or 10, the active layer of the drive transistor T4 includes a polysilicon semiconductor material, and the active layer of the data writing transistor T1 includes an oxide semiconductor material. That is, the drive transistor T4 is a P-type transistor, and the data writing transistor T1 is an N-type transistor. This allows transistors of different types to be stacked, thereby reducing the area occupied by the pixel circuit.

In the pixel circuit provided in this embodiment, a number of transistors is small, and the pixel circuit may perform functions: reset, data writing, and threshold compensation. This ensures the normal operation of the pixel circuit while increasing the pixel density of the display panel, which is conducive to improving the accuracy and stability of the drive current generated by the pixel circuit, thereby improving the display quality of the display panel.

An operation process of the pixel circuit will be described below with reference to a structure of the pixel circuit and a drive timing of the pixel circuit. However, this is not intended to limit the present application.

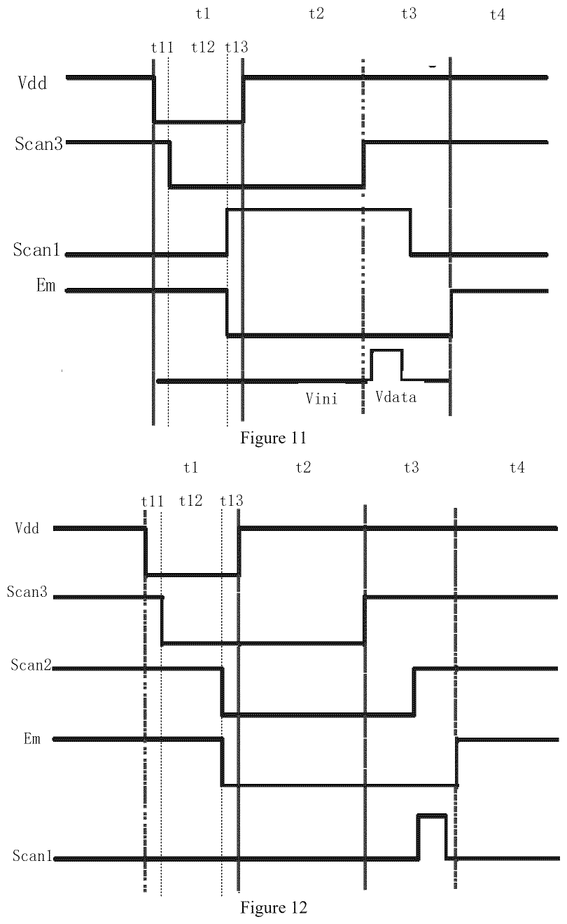

In one embodiment, FIG. 11 is a drive timing diagram of a pixel circuit according to an embodiment of the present disclosure. referring to FIGS. 8 and 11, a driving process (i.e., one drive cycle) of the pixel circuit includes the following several phases.

In a first sub-phase t11 of a reset phase t1, a first power signal Vdd on the first power line VDD jumps from the first power voltage to the second reset voltage. FIG. 11 shows a case in which the second reset voltage is less than the first power voltage, but this is not intended to be limiting. Thus, a control electrode g of the drive transistor T4 may be coupled downward to a second electrode n1 of the coupling capacitor C1.

In a second sub-phase t12 of the reset phase t1, a third scan signal Scan3 on the third scan line S3 is at a low level, and the threshold compensation transistor T3 is turned on, which results in a short circuit between the control electrode g of the drive transistor T4 and the second electrode of the drive transistor T4. After a period of leakage, a voltage Vg at the control electrode g of the drive transistor T4 and a voltage at the second electrode of the drive transistor T4 are both equal to a second reset voltage Vdd1, that is, Vg=Vdd1. In this way, the control electrode g of the drive transistor T4 is reset. Moreover, a light emission control signal Em on the light emission control line EM is at a high level, and the light emission control transistor T5 is turned on, the light emission control transistor T5 transmits the second reset voltage to the first terminal of the light-emitting element 200, to reset the first terminal of the light-emitting element 200.

In a third sub-phase t13 of the reset phase t1, a third scan signal Scan3 on the third scan line S3 is at a low level, and the threshold compensation transistor T3 is turned on. A first scan signal Scan1 on the first scan line S1 is at a high level, the data writing transistor T1 is turned on. In this case, the data writing transistor T1 is connected to the first reset voltage Vini, and the data writing transistor T1 transmits the first reset voltage Vini to the second electrode n1 of the coupling capacitor C1, to reset the second electrode n1 of the coupling capacitor C1. Moreover, the coupling capacitor C1 couples the control electrode of the drive transistor T4, the potential at the control electrode g of the drive transistor T4 is slightly pulled up but the voltage at the control electrode g of the drive transistor T4 still remains at a low voltage, thereby resetting the control electrode of the drive transistor T4.

In a threshold compensation phase t2, the third scan signal Scan3 on the third scan line S3 is at a low level, and the threshold compensation transistor T3 is turned on. The first scan signal Scan1 on the first scan line S1 is at a high level, and the data writing transistor T1 is turned on. In this case, the data writing transistor T1 is connected to the first reset voltage Vini. The light emission control signal Em on the light emission control line EM is at a low level, and the light emission control transistor T5 is not turned on. The first power signal Vdd on the first power line VDD changes to a first power voltage Vdd2. The first power voltage Vdd2 charges the first electrode of the coupling capacitor C1 through the drive transistor T4 and the threshold compensation transistor T3, until a voltage at the first electrode of the coupling capacitor C1 is Vdd2+Vth (Vth is the threshold voltage of the drive transistor T4), that is, the voltage at the control electrode g of the drive transistor T4 is Vdd2+Vth. The data writing transistor T1 transmits the first reset voltage Vini to the second electrode n1 of the coupling capacitor C1, a voltage at the second electrode n1 of the coupling capacitor C1 is maintained at the first reset voltage Vini. In this way, the threshold compensation transistor T3 performs threshold compensation on the drive transistor T4.

In a data writing phase t3, the first scan signal Scan1 on the first scan line S1 is at a high level, and the data writing transistor T1 is turned on. In this case, the data writing transistor T1 is connected to the data voltage Vdata. The third scan signal Scan3 on the third scan line S3 is at a high level, and the threshold compensation transistor T3 is not turned on. The data writing transistor T1 transmits the data voltage Vdata to the second electrode n1 of the coupling capacitor C1, and then a voltage variation of the first electrode of the coupling capacitor C1 is k*(Vdata−Vini), where

$$k = \frac{C 1}{C 1 + Cother} ,$$

with C1 being a capacitance value of the coupling capacitor C1, and Cother being another capacitance at the control electrode of the drive transistor T4. Then, the potential at the control electrode of the drive transistor T4 changes to Vdd2+Vth+k*(Vdata−Vini). For example, if the another capacitance at the control electrode of the drive transistor T4 is small enough to be negligible, k is 1, and the potential at the control electrode of the drive transistor T4 is Vdd2+Vth+(Vdata−Vini).

In a light emission phase t4, the light emission control signal Em on the light emission control line EM is at a high level, and the light emission control transistor T5 is turned on. This allows the first power line VDD, the drive transistor T4, the light emission control transistor T5, the light-emitting element 200, and the second power line VSS form a current path. In this case, a voltage difference between the control electrode of the drive transistor T4 and the first electrode of the drive transistor T4 is Vth+(Vdata−Vini), and then the drive current generated by the drive transistor T4 is

$$I = \frac{1}{2} μ * Cox * \frac{W}{L} * ( Vdata - Vini ) .$$

Here, μ is an electron mobility of the drive transistor T4 in the drive sub-circuit 110, Cox is a channel capacitance per unit area of the drive transistor T4, W is a channel width of the drive transistor T4, and L is a channel length of the drive transistor T4. Thus, the drive current generated by the drive sub-circuit 110 is related only to the data voltage Vdata and the first reset voltage Vini, and is independent of the threshold voltage of the drive transistor T4 in the drive sub-circuit 110, as well as the first power voltage and the second power voltage. This may avoid a fluctuation in the drive current caused by a fluctuation in the threshold voltage of the drive transistor T4, and may avoid a fluctuation in the drive current caused by a voltage drop on the first power line VDD or the second power line VSS. As a result, the stability and accuracy of the drive current are ensured, which is conducive to improving the display effect of the display panel, and improving the display performance of the display panel.

In another embodiment, FIG. 12 is a drive timing diagram of another pixel circuit according to an embodiment of the present disclosure. referring to FIGS. 9 and 12, a driving process (i.e., one drive cycle) of the pixel circuit includes the following several phases.

In a first sub-phase t11 of a reset phase t1, a first power signal Vdd on the first power line VDD jumps from the first power voltage to the second reset voltage. Thus, a control electrode g of the drive transistor T4 may be coupled downward to a second electrode n1 of the coupling capacitor C1.

In a second sub-phase t12 of the reset phase t1, a third scan signal Scan3 on the third scan line S3 is at a low level, and the threshold compensation transistor T3 is turned on, which results in a short circuit between the control electrode g of the drive transistor T4 and the second electrode of the drive transistor T4. After a period of leakage, a voltage Vg at the control electrode g of the drive transistor T4 and a voltage at the second electrode of the drive transistor T4 are both equal to a second reset voltage Vdd1, that is, Vg=Vdd1. In this way, the control electrode g of the drive transistor T4 is reset, while resetting a first electrode s of the drive transistor T4. Moreover, a light emission control signal Em on the light emission control line EM is at a high level, and the light emission control transistor T5 is turned on, the light emission control transistor T5 transmits the second reset voltage to the first terminal of the light-emitting element 200, to reset the first terminal of the light-emitting element 200.

In a third sub-phase t13 of the reset phase t1, a third scan signal Scan3 on the third scan line S3 is at a low level, and the threshold compensation transistor T3 is turned on. A first scan signal Scan1 on the first scan line S1 is at a low level, and the data writing transistor T1 is not turned on. A second scan signal Scan2 on a second scan line S2 is at a low level, and the reset transistor T2 is turned on. In this case, the reset transistor T2 transmits the first reset voltage Vini to the second electrode n1 of the coupling capacitor C1, to reset the second electrode n1 of the coupling capacitor C1. Moreover, the coupling capacitor C1 couples the control electrode of the drive transistor T4, the potential at the control electrode g of the drive transistor T4 is slightly pulled up but the voltage at the control electrode g of the drive transistor T4 still remains at a low voltage, thereby resetting the control electrode of the drive transistor T4.

In a threshold compensation phase t2, the third scan signal Scan3 on the third scan line S3 is at a low level, and the threshold compensation transistor T3 is turned on. The first scan signal Scan1 on the first scan line S1 is at a low level, and the data writing transistor T1 is not turned on. The second scan signal Scan2 on the second scan line S2 is at a low level, and the reset transistor T2 is turned on. The light emission control signal Em on the light emission control line EM is at a low level, and the light emission control transistor T5 is not turned on. The first power signal Vdd on the first power line VDD changes to a first power voltage Vdd2. The first power voltage Vdd2 charges the first electrode of the coupling capacitor C1 through the drive transistor T4 and the threshold compensation transistor T3, until a voltage at the first electrode of the coupling capacitor C1 is Vdd2+Vth (Vth is the threshold voltage of the drive transistor T4), that is, the voltage at the control electrode g of the drive transistor T4 is Vdd2+Vth. The reset transistor T2 transmits the first reset voltage Vini to the second electrode n1 of the coupling capacitor C1, a voltage at the second electrode n1 of the coupling capacitor C1 is maintained at the first reset voltage Vini. In this way, the threshold compensation transistor T3 performs threshold compensation on the drive transistor T4.

In a data writing phase t3, the first scan signal Scan1 on the first scan line S1 is at a high level, and the data writing transistor T1 is turned on. The third scan signal Scan3 on the third scan line S3 and the second scan signal Scan2 on the second scan line S2 are at a high level, and the reset transistor T2 and the threshold compensation transistor T3 are not turned on. The data writing transistor T1 transmits the data voltage Vdata to the second electrode n1 of the coupling capacitor C1, and then a voltage variation of the first electrode of the coupling capacitor C1 is k*(Vdata−Vini), where

$$k = \frac{C 1}{C 1 + Cother} ,$$

with C1 being a capacitance value of the coupling capacitor C1, and Cother being another capacitance at the control electrode of the drive transistor T4. Then, the potential at the control electrode of the drive transistor T4 changes to Vdd2+Vth+k*(Vdata−Vini). For example, if the another capacitance at the control electrode of the drive transistor T4 is small enough to be negligible, k is 1, and the potential at the control electrode of the drive transistor T4 is Vdd2+Vth+(Vdata−Vini).

In a light emission phase t4, the light emission control signal Em on the light emission control line EM is at a high level, and the light emission control transistor T5 is turned on. This allows the first power line VDD, the drive transistor T4, the light emission control transistor T5, the light-emitting element 200, and the second power line VSS form a current path. In this case, a voltage difference between the control electrode of the drive transistor T4 and the first electrode of the drive transistor T4 is Vth+(Vdata−Vini), and then the drive current generated by the drive transistor T4 is

$$I = \frac{1}{2} μ * Cox * \frac{W}{L} * ( Vdata - Vini ) .$$

Here, μ is an electron mobility of the drive transistor T4 in the drive sub-circuit 110, Cox is a channel capacitance per unit area of the drive transistor T4, W is a channel width of the drive transistor T4, and L is a channel length of the drive transistor T4. Thus, the drive current generated by the drive sub-circuit 110 is related only to the data voltage Vdata and the first reset voltage Vini, and is independent of the threshold voltage of the drive transistor T4 in the drive sub-circuit 110, as well as the first power voltage and the second power voltage. This may avoid a fluctuation in the drive current caused by a fluctuation in the threshold voltage of the drive transistor T4, and may avoid a fluctuation in the drive current caused by a voltage drop on the first power line VDD or the second power line VSS. As a result, the stability and accuracy of the drive current are ensured, which is conducive to improving the display effect of the display panel, and improving the display performance of the display panel.

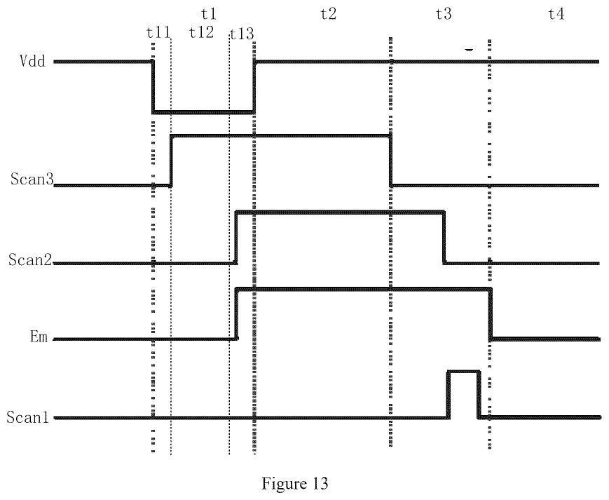

In still another embodiment, FIG. 13 is a drive timing diagram of another pixel circuit according to an embodiment of the present disclosure. referring to FIGS. 10 and 13, a driving process (i.e., one drive cycle) of the pixel circuit includes the following several phases.

In a first sub-phase t11 of a reset phase t1, a first power signal Vdd on the first power line VDD jumps from the first power voltage to the second reset voltage. Thus, a control electrode g of the drive transistor T4 may be coupled downward to a second electrode n1 of the coupling capacitor C1.

In a second sub-phase t12 of the reset phase t1, a third scan signal Scan3 on the third scan line S3 is at a high level, and the threshold compensation transistor T3 is turned on, which results in a short circuit between the control electrode g of the drive transistor T4 and the second electrode of the drive transistor T4. After a period of leakage, a voltage Vg at the control electrode g of the drive transistor T4 and a voltage at the second electrode of the drive transistor T4 are both equal to a second reset voltage Vdd1, that is, Vg=Vdd1. In this way, the control electrode g of the drive transistor T4 is reset. Moreover, a light emission control signal Em on the light emission control line EM is at a low level, and the light emission control transistor T5 is turned on, the light emission control transistor T5 transmits the second reset voltage to the first terminal of the light-emitting element 200, to reset the first terminal of the light-emitting element 200.

In a third sub-phase t13 of the reset phase t1, a third scan signal Scan3 on the third scan line S3 is at a high level, and the threshold compensation transistor T3 is turned on. A first scan signal Scan1 on the first scan line S1 is at a low level, and the data writing transistor T1 is not turned on. A second scan signal Scan2 on a second scan line S2 is at a high level, and the reset transistor T2 is turned on. In this case, the reset transistor T2 transmits the first reset voltage Vini to the second electrode n1 of the coupling capacitor C1, to reset the second electrode n1 of the coupling capacitor C1. Moreover, the coupling capacitor C1 couples the control electrode of the drive transistor T4, the potential at the control electrode g of the drive transistor T4 is slightly pulled up but the voltage at the control electrode g of the drive transistor T4 still remains at a low voltage, thereby resetting the control electrode of the drive transistor T4.

In a threshold compensation phase t2, the third scan signal Scan3 on the third scan line S3 is at a high level, and the threshold compensation transistor T3 is turned on. The first scan signal Scan1 on the first scan line S1 is at a low level, and the data writing transistor T1 is not turned on. The second scan signal Scan2 on the second scan line S2 is at a high level, and the reset transistor T2 is turned on. The light emission control signal Em on the light emission control line EM is at a high level, and the light emission control transistor T5 is not turned on. The first power signal Vdd on the first power line VDD changes to a first power voltage Vdd2. The first power voltage Vdd2 charges the first electrode of the coupling capacitor C1 through the drive transistor T4 and the threshold compensation transistor T3, until a voltage at the first electrode of the coupling capacitor C1 is Vdd2+Vth (Vth is the threshold voltage of the drive transistor T4), that is, the voltage at the control electrode g of the drive transistor T4 is Vdd2+Vth. The reset transistor T2 transmits the first reset voltage Vini to the second electrode n1 of the coupling capacitor C1, a voltage at the second electrode n1 of the coupling capacitor C1 is maintained at the first reset voltage Vini. In this way, the threshold compensation transistor T3 performs threshold compensation on the drive transistor T4.

In a data writing phase t3, the first scan signal Scan1 on the first scan line S1 is at a high level, and the data writing transistor T1 is turned on. The third scan signal Scan3 on the third scan line S3 and the second scan signal Scan2 on the second scan line S2 are at a low level, and the reset transistor T2 and the threshold compensation transistor T3 are not turned on. The data writing transistor T1 transmits the data voltage Vdata to the second electrode n1 of the coupling capacitor C1, and then a voltage variation of the first electrode of the coupling capacitor C1 is k*(Vdata−Vini), where

$$k = \frac{C 1}{C 1 + Cother} ,$$

with C1 being a capacitance value of the coupling capacitor C1, and Cother being another capacitance at the control electrode of the drive transistor T4. Then, the potential at the control electrode of the drive transistor T4 changes to Vdd2+Vth+k*(Vdata−Vini). For example, if the another capacitance at the control electrode of the drive transistor T4 is small enough to be negligible, k is 1, and the potential at the control electrode of the drive transistor T4 is Vdd2+Vth+(Vdata−Vini).

In a light emission phase t4, the light emission control signal Em on the light emission control line EM is at a low level, and the light emission control transistor T5 is turned on. This allows the first power line VDD, the drive transistor T4, the light emission control transistor T5, the light-emitting element 200, and the second power line VSS form a current path. In this case, a voltage difference between the control electrode of the drive transistor T4 and the first electrode of the drive transistor T4 is Vth+(Vdata−Vini), and then the drive current generated by the drive transistor T4 is

$$I = \frac{1}{2} μ * Cox * \frac{W}{L} * ( Vdata - Vini ) .$$

Here, μ is an electron mobility of the drive transistor T4 in the drive sub-circuit 110, Cox is a channel capacitance per unit area of the drive transistor T4, W is a channel width of the drive transistor T4, and L is a channel length of the drive transistor T4. Thus, the drive current generated by the drive sub-circuit 110 is related only to the data voltage Vdata and the first reset voltage Vini, and is independent of the threshold voltage of the drive transistor T4 in the drive sub-circuit 110, as well as the first power voltage and the second power voltage. This may avoid a fluctuation in the drive current caused by a fluctuation in the threshold voltage of the drive transistor T4, and may avoid a fluctuation in the drive current caused by a voltage drop on the first power line VDD or the second power line VSS. As a result, the stability and accuracy of the drive current are ensured, which is conducive to improving the display effect of the display panel, and improving the display performance of the display panel.

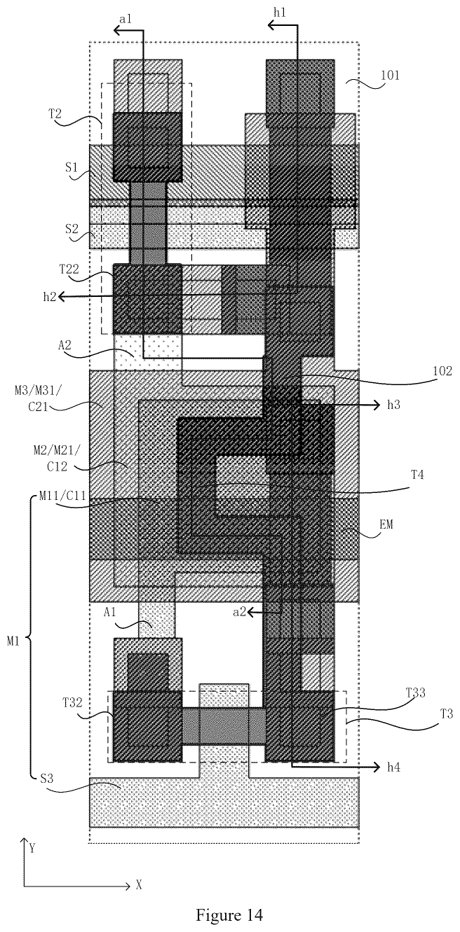

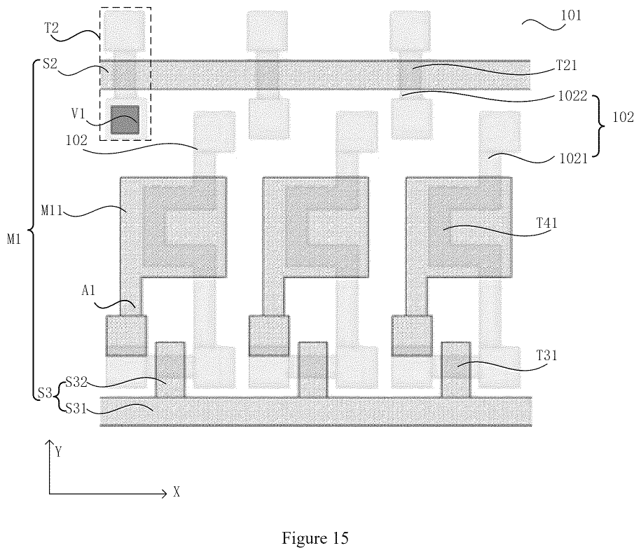

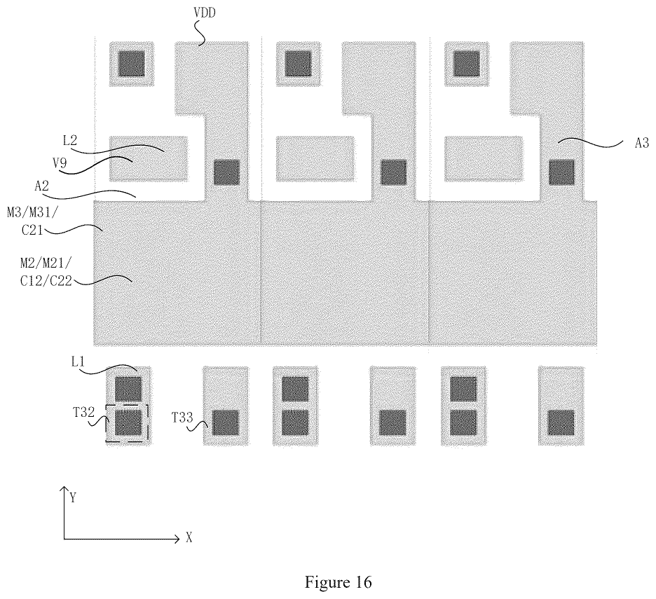

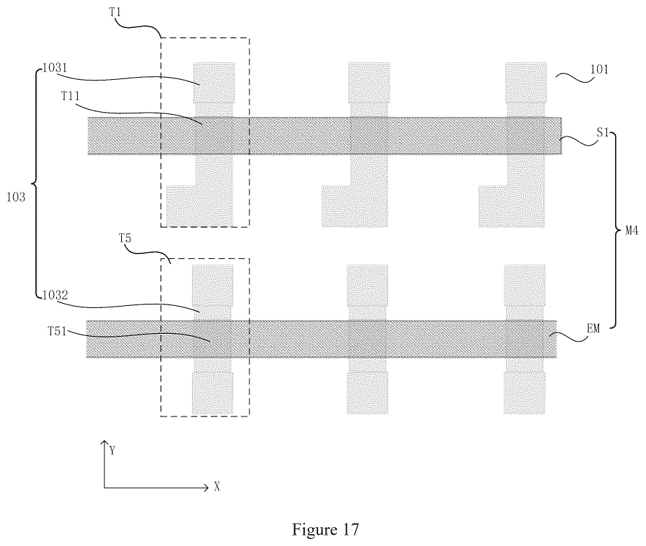

An embodiment of the present disclosure further provides an array substrate, including the pixel circuit according to any one of the embodiments of the present disclosure. FIG. 14 is a schematic structural top view of an array substrate according to an embodiment of the present disclosure, FIG. 15 is a schematic view of a layout structure of a first active layer and a first conductive layer of an array substrate according to an embodiment of the present disclosure; FIG. 16 is a schematic view of a layout structure of a second conductive layer and a third conductive layer of an array substrate according to an embodiment of the present disclosure; and FIG. 17 is a schematic view of a layout structure of a second active layer and a fourth conductive layer of an array substrate according to an embodiment of the present disclosure. Referring to FIGS. 14, 15, 16, and 17, the array substrate includes:
a base substrate 101;
a first active layer 102 located on a side of the base substrate 101, the first active layer 102 including a first active region 1021, and the first active region 1021 being provided with a channel region T41 of a drive transistor T4 and a channel region T31 of a threshold compensation transistor T3;
a first conductive layer M1 located on a side of the first active layer 102 facing away from the base substrate 101, the first conductive layer M1 including a first metal block M11 forming a control electrode of the drive transistor T4 and a third scan line S3 forming a control electrode of the threshold compensation transistor T3, the third scan line S3 extending in a first direction X, the channel region T41 of the drive transistor T4 being located at an orthographic projection of the first metal block M11 on the first active region 1021, the channel region T31 of the threshold compensation transistor T3 being located at an orthographic projection of the third scan line S3 on the first active region 1021, the first metal block M11 being connected to a first electrode T32 of the threshold compensation transistor T3 through a first connection portion L1, and a second electrode of the drive transistor T4 being connected to a second electrode of the threshold compensation transistor T3 through the first active region 1021;
a second conductive layer M2 located on a side of the first conductive layer M1 facing away from the base substrate 101, the second conductive layer M2 including a second metal block M21 forming a second electrode C12 of a coupling capacitor C1, the first metal block M21 being reused as a first electrode C11 of the coupling capacitor C1, and an orthographic projection of the second metal block M21 on the base substrate 101 covering an orthographic projection of the first metal block M11 on the base substrate 101;
a second active layer 103 located on a side of the second conductive layer M2 facing away from the base substrate 101, the second active layer 103 including a third active region 1031, and the third active region 1031 being provided with a channel region T11 of a data writing transistor T1; and
a fourth conductive layer M4 located on a side of the second active layer 103 facing away from the base substrate 101, the fourth conductive layer M4 including a first scan line S1 forming a control electrode of the data writing transistor T1, the first scan line S1 extending in the first direction X, the channel region T11 of the data writing transistor T1 being located at an orthographic projection of the first scan line S1 on the third active region 1031, and a second electrode T12 of the data writing transistor T1 being connected to the second metal block M21 through a second connection portion L2, where the first active layer 102 and the second active layer 103 are made of different materials.

Here, for example, the first direction X is a row direction. A portion where the first scan line S1 overlaps with the third active region 1031 forms a control electrode of the data writing transistor T1, and a portion where the third scan line S3 overlaps with the first active region 1021 may form the control electrode of the threshold compensation transistor T3. This may reduce the number of electrodes and increase the space utilization.
with the configuration that active layers made of different materials (the first active layer 102 and the third active layer 103) are stacked, transistors of different types may be stacked. This maximizes the space utilization and results in a high pixel density of a display panel formed by the array substrate. Moreover, the array substrate includes the threshold compensation transistor T3 to ensure that the pixel circuit may perform threshold compensation and reset functions while increasing the pixel density, thereby ensuring the normal operation of the pixel circuit.

On the basis of the above-mentioned embodiment, referring to FIGS. 14 and 15, the first active layer 102 further includes a second active region 1022, the second active region 1022 including a channel region T21 of a reset transistor T2, and a second electrode T22 of the reset transistor T2 being connected to the second electrode C12 of the coupling capacitor C1.

The first conductive layer M1 further includes a second scan line S2 extending in the first direction X, and the channel region T21 of the reset transistor T2 is located at an orthographic projection of the second scan line S2 on the second active region 1022.
a portion where the second scan line S2 overlaps with the second active region 1022 forms a control electrode of the reset transistor T2. This may reduce the number of electrodes and increase the space utilization. The second electrode T22 of the reset transistor T2 is connected to the second electrode C12 of the coupling capacitor C1, to write a first reset voltage Vini to the second electrode C12 of the coupling capacitor C1, the coupling capacitor C1 may reset a control electrode of the drive transistor T4 through coupling.
as shown in FIGS. 14 and 15, an extension direction of the channel region T31 of the threshold compensation transistor T3 is arranged perpendicular to an extension direction of the channel region T21 of the reset transistor T2. In this way, a space occupied in the first direction X may be reduced compared to arranging the channel region T31 of the threshold compensation transistor T3 and the channel region T21 of the reset transistor T2 sequentially in the first direction X. A space occupied in a second direction Y may be reduced compared to arranging the channel region T31 of the threshold compensation transistor T3 and the channel region T21 of the reset transistor T2 sequentially in the second direction Y. This may increase the space utilization of the array substrate.
as shown in FIGS. 14 and 15, in a second direction Y, the channel region T31 of the threshold compensation transistor T3 and the channel region T21 of the reset transistor T2 are distributed on two sides of the channel region T41 of the drive transistor T4, the first direction X intersecting the second direction Y. In this way, the space occupied in the first direction X may be reduced, a plurality of pixel circuits are arranged in the first direction X, thereby increasing the pixel density of the display panel formed by the array substrate.
as shown in FIGS. 14 and 15, the first metal block M11 includes a first protrusion A1, the first protrusion A1 being located at an end of the first metal block M11 facing the threshold compensation transistor T3, and the first electrode T32 of the threshold compensation transistor T3 being connected to the first protrusion A1. This facilitates the connection of the first electrode T32 of the threshold compensation transistor T3 to the first metal block M11 through the first protrusion A1, that is, to the control electrode of the drive transistor T4. This allows the threshold compensation transistor T3 to perform threshold compensation on the drive transistor T4 and reset the drive transistor in a time-division manner.

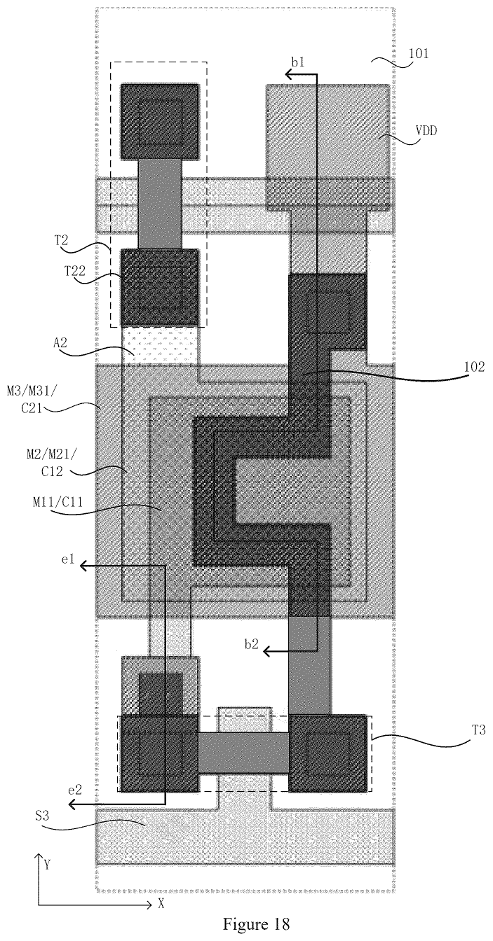

FIG. 18 is a schematic structural view of a first active layer, a first conductive layer, a second conductive layer, and a third conductive layer of an array substrate according to an embodiment of the present disclosure. as shown in FIGS. 14, 16, and 18, the second metal block M21 includes a second protrusion A2, the second protrusion A2 being located at an end of the second metal block M21 facing the reset transistor T2, and the second electrode T22 of the reset transistor T2 being electrically connected to the second protrusion A2. This facilitates the connection of the reset transistor T2 to the second metal block M21, and thus to the second electrode C12 of the coupling capacitor C1, to write the first reset voltage Vini to the second electrode C12 of the coupling capacitor C1, the coupling capacitor C1 may reset the control electrode of the drive transistor T4 through coupling.

On the basis of the above-mentioned embodiments, referring to FIG. 17, the second active layer 103 further includes a fourth active region 1032, the fourth active region 1032 including a channel region T51 of a light emission control transistor T5, and the third active region 1031 and the fourth active region 1032 being spaced apart and each extending in the second direction Y. In this way, the space occupied in the first direction X may be further reduced, a plurality of pixel circuits are arranged in the first direction X, thereby increasing the pixel density of the display panel formed by the array substrate.
an orthographic projection of the third active region 1031 on the base substrate 101 and an orthographic projection of the fourth active region 1032 on the base substrate 101 both partially overlap with an orthographic projection of the first active region 1021 on the base substrate. In this way, spaces occupied in both the first direction X and the second direction Y may be reduced, thereby increasing the space utilization and achieving a high pixel density.
referring to FIG. 17, the fourth conductive layer M4 further includes a light emission control line EM extending in the first direction X, and the channel region T51 of the light emission control transistor T5 is located at an orthographic projection of the light emission control line EM on the fourth active region 1032. Thus, a portion where the light emission control line EM overlaps with the fourth active region 1032 forms a control electrode of the light emission control transistor T5. This may reduce the number of electrodes and increase the space utilization.
referring to FIGS. 15 and 17, the channel region T41 of the drive transistor T4 is II-shaped, and the third active region 1031 is L-shaped.
the channel region T41 of the drive transistor T4 is II-shaped, and the drive transistor T4 is separately connected to the threshold compensation transistor T3 and the reset transistor T2 located on two sides of the drive transistor. The third active region 1031 is L-shaped, and the data writing transistor T1 is connected to the second metal block M21.

On the basis of the above-mentioned embodiment, referring to FIGS. 14 and 16, the array substrate further includes a third conductive layer M3 located between the second conductive layer M2 and the second active layer 103;
the third conductive layer M3 includes a third metal block M31 forming a first electrode C21 of a storage capacitor C2, an orthographic projection of the third metal block M31 on the base substrate 101 covering the orthographic projection of the second metal block M21 on the base substrate 101, and the second metal block M21 being reused as a second electrode C22 of the storage capacitor C2; and
in the first direction X, adjacent third metal blocks M31 are interconnected, the interconnected third metal blocks M31 being reused as the first power line VDD to transmit a first power signal, and the first electrode C21 of the storage capacitor C2 being connected to a first electrode of the drive transistor T4.

With the configuration that the second metal block M21 is reused as the second electrode C22 of the storage capacitor C2, the number of electrodes can be reduced, thereby reducing the thickness of the array substrate and achieving a thin and lightweight design. Moreover, the third metal block M31 is reused as the first power line VDD to transmit the first power signal. This may reduce a space occupied by traces, thereby further increasing the space utilization of the array substrate and helping to increase the pixel density of the display panel formed by the array substrate.

Referring to FIG. 16, the third metal block M31 includes a third protrusion A3, the third protrusion A3 extending toward the third active region 1031. Thus, the third metal block M31 extends to a position of the third active region 1031, the formed first power line VDD overlaps with the third active region 1031. This reduces space occupation and further increases the space utilization of the array substrate.

Referring to FIG. 16, the first connection portion L1 and the second connection portion L2 are both located in the third conductive layer M3. This arrangement allows the first electrode T32 of the threshold compensation transistor T3 located in the third conductive layer M3 to be connected to the coupling capacitor C1 through the first connection portion L1 located in third conductive layer M3, that is, the first connection portion L1 functions as a jumper. This arrangement also allows the second electrode T12 of the data writing transistor T1 that is located on a side of the conductive layer M3 away from the base substrate 101 to be connected to the second metal block M21 through the second connection portion L2, that is, the second connection portion L2 functions as a jumper.

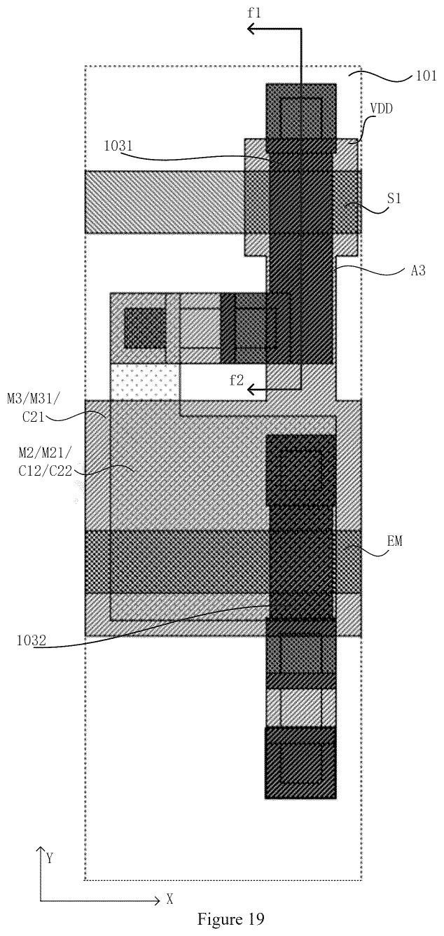

FIG. 19 is a schematic view of a layout structure of a second conductive layer, a third conductive layer, a second active layer, and a fourth conductive layer of an array substrate according to an embodiment of the present disclosure. Referring to FIG. 19, the orthographic projection of the third active region 1031 on the base substrate 101 and the orthographic projection of the fourth active region 1032 on the base substrate are within the orthographic projection of the third metal block M31 on the base substrate 101. In this way, the space occupied in the second direction Y may be reduced, a larger number of pixel circuits may be arranged in the second direction Y. This further increases the space utilization of the array substrate, thereby increasing the pixel density of the display panel formed by the array substrate, and helping to improve the display quality of the display panel.

Referring to FIG. 15, the third scan line S3 includes a body portion S31 and an extension portion S32, the body portion S31 having a same extension direction as that of the channel region T31 of the threshold compensation transistor T3, an extension direction of the extension portion S32 being arranged perpendicular to the extension direction of the body portion S31, and the channel region T31 of the threshold compensation transistor T3 being located at an orthographic projection of the extension portion on the first active region 1021.

With the configuration that the third scan line S3 includes the body portion S31 and the extension portion S32, the body portion S31 extends in the first direction X and may be connected to threshold compensation transistors T3 in the plurality of pixel circuits, facilitating row-by-row driving. In addition, the extension portion S32 may be connected to a corresponding threshold compensation transistor T3. Moreover, the extension portion S32 overlaps with the first active region 1021 to form the control electrode of the threshold compensation transistor T3. This reduces the number of electrodes and may further increase the space utilization.

The body portion S31 has a same width as that of the first scan line S1. This facilitates the preparation of the scan line, and both the body portion S31 and the first scan line S1 can be made narrow, which helps to save space and increase the space utilization. In some embodiments, for example, the body portion S31 has the same width as that of the second scan line S2.

On the basis of the above-mentioned embodiment, the second conductive layer M2 further includes a plurality of reset power signal lines Vin extending in the first direction X, an orthographic projection of the reset power signal lines Vin on the base substrate 101 partially overlapping with an orthographic projection of a first electrode T23 of the reset transistor T2 on the base substrate 101, and the first electrode T23 of the reset transistor T2 being connected to the reset power signal lines Vin.

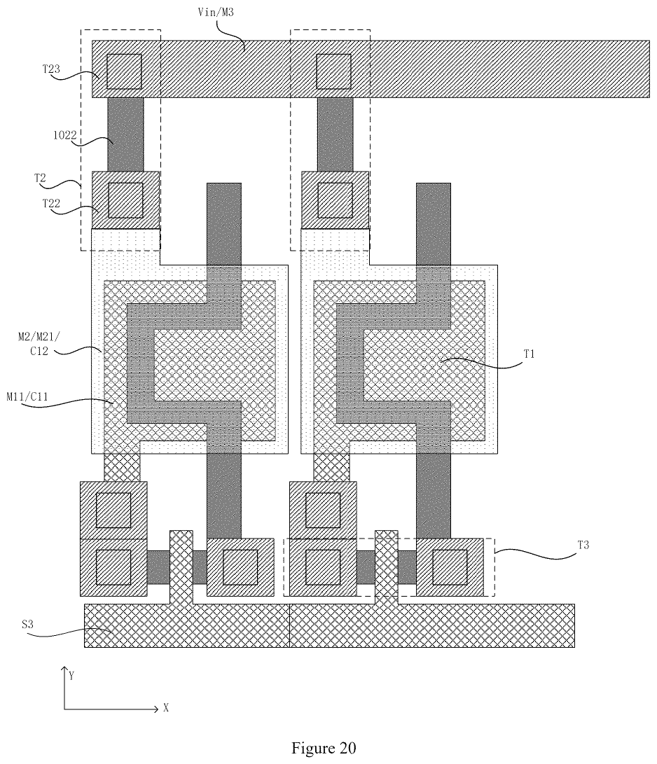

FIG. 20 is a schematic structural top view of another array substrate according to an embodiment of the present disclosure. Referring to FIG. 20, the third conductive layer M3 further includes a plurality of reset power signal lines Vin, an orthographic projection of the reset power signal line Vin on the base substrate 101 partially overlapping with an orthographic projection portion of a first electrode T23 of the reset transistor T2 on the base substrate 101, and the first electrode T23 of the reset transistor T2 being connected to the reset power signal lines Vin; and
the reset power signal lines Vin extend in the first direction X, and an end of the second active region 1022 away from the second metal block M21 is electrically connected to one of the reset signal lines Vin.

The reset power signal lines Vin extend in the first direction X, allowing the reset power signal lines Vin to be connected to reset transistors T2 in the plurality of pixel circuits, thereby providing the plurality of pixel circuits with the first reset voltage Vini. The reset power signal lines Vin are connected to the first electrode T23 of the reset transistor T2, the reset transistor T2 may transmit the first reset voltage Vini on the reset power signal lines Vin to the second electrode of the coupling capacitor C1, to reset the second electrode of the coupling capacitor C1.

FIG. 20 shows a case in which the reset power signal lines Vin are located in the third conductive layer M3, but this is not intended to be limiting.

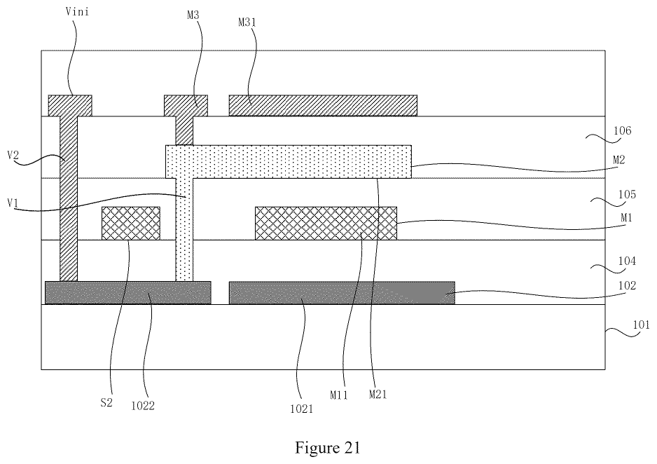

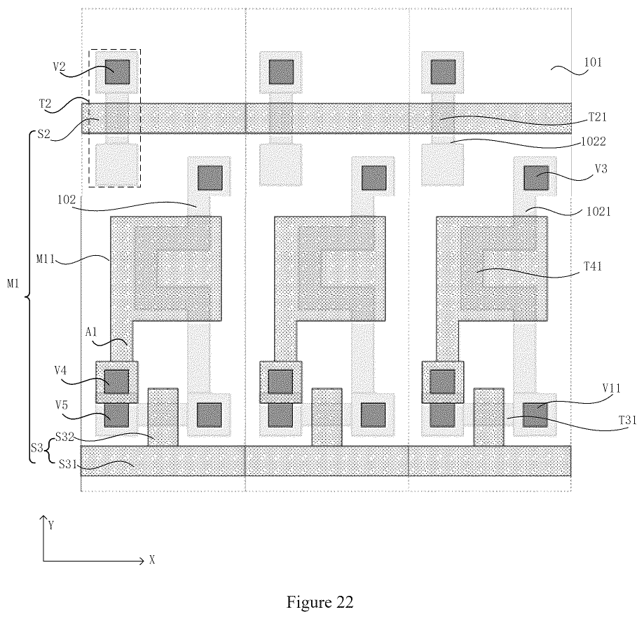

On the basis of the above-mentioned embodiment, FIG. 21 is a sectional view of FIG. 14 taken along line a1-a2, and FIG. 22 is a schematic view of a layout structure of a first active layer, a first conductive layer, and a third active layer of an array substrate according to an embodiment of the present disclosure. Referring to FIGS. 20, 21, and 22, the array substrate further includes a first insulation layer 104 located between the first active layer 102 and the first conductive layer M1, a second insulation layer 105 located between the first conductive layer M1 and the second conductive layer M2, and a third insulation layer 106 located between the second conductive layer M2 and the third conductive layer M3; and
the second electrode of the reset transistor T2 is connected to the second metal block M21 through a first via V1 that extends through the first insulation layer 104 and the second insulation layer 105, and the first electrode of the reset transistor T2 is connected to the reset power signal lines Vin through a second via V2, the second via V2 extending through the first insulation layer 104 and the second insulation layer 105, or the second via V2 extending through the first insulation layer 104, the second insulation layer 105, and the third insulation layer 106. This facilitates the connection of the reset transistor T2 to the reset power signal lines Vin, and the connection of the reset transistor T2 to the second metal block M21 (i.e., the second electrode of the coupling capacitor C1). Here, the first insulation layer 104 may be an organic insulation layer or an inorganic insulation layer. The second insulation layer 105 may be an organic insulation layer or an inorganic insulation layer, such as an insulation layer formed by silicon dioxide or silicon nitride. The third insulation layer 106 may be an inorganic insulation layer or an organic insulation layer. For example, the third insulation layer 106 and the second insulation layer 105 are made of the same material, which is not limited in this embodiment.

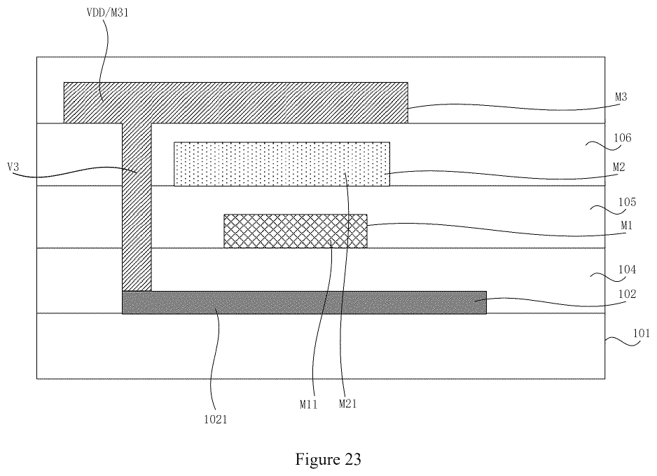

FIG. 23 is a sectional view of FIG. 18 taken along line b1-b2. Referring to FIGS. 18, 22, and 23, the first electrode of the drive transistor T4 is connected to the third metal block M31 through a third via V3, the third via V3 extending through the first insulation layer 104, the second insulation layer 105, and the third insulation layer 106. This facilitates the connection of the first electrode of the drive transistor T4 to the third metal block M31, that is, the connection of the drive transistor T4 to the first power line VDD.

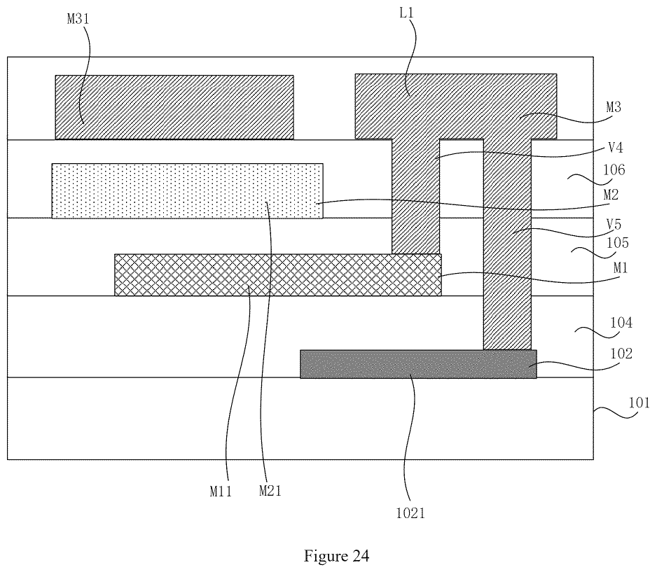

FIG. 24 is a sectional view of FIG. 18 taken along line e1-e2. Referring to FIGS. 18, 22, and 23, the control electrode of the drive transistor T4 is connected to the first connection portion L1 through a fourth via V4, and the first connection portion L1 is further connected to the first electrode of the threshold compensation transistor T3 through a fifth via V5; and
the fourth via V4 extends through the second insulation layer 105 and the third insulation layer 106, and the fifth via V5 sequentially extends through the third insulation layer 106, the second insulation layer 105, and the first insulation layer 104. In this way, the control electrode of the drive transistor T4 is connected to the first electrode of the threshold compensation transistor T3 through the first connection portion L1, the threshold compensation transistor T3 resets the drive transistor T4 and performs threshold compensation on the drive transistor.

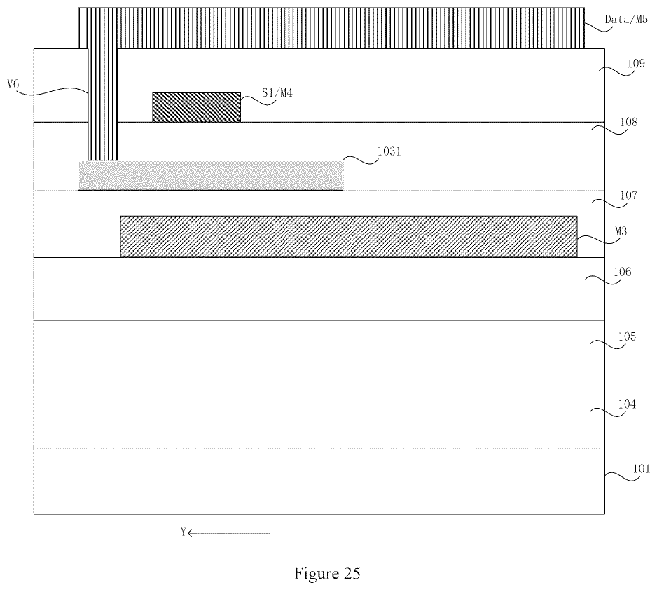

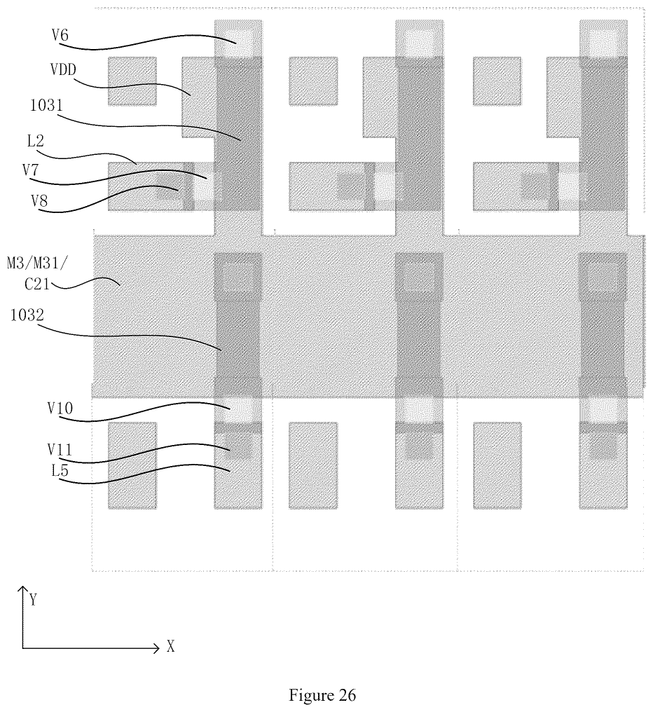

On the basis of the above-mentioned embodiment, FIG. 25 is a sectional view of FIG. 19 taken along line f1-f2, and FIG. 26 is a schematic view of a layout structure of a third conductive layer, a second active layer, and a sixth insulation layer of an array substrate according to an embodiment of the present disclosure. Referring to FIGS. 25 and 26, the array substrate further includes a fourth insulation layer 107 located between the third conductive layer M3 and the second active layer 103, a fifth insulation layer 108 located between the second active layer 103 and the fourth conductive layer M4, and a sixth insulation layer 109 located on a side of the fourth conductive layer M4 facing away from the base substrate 101; and
the fifth conductive layer M5 includes a plurality of data transmission lines Data extending in the second direction Y, and a first electrode of the data writing transistor T1 is connected to the data transmission lines Data through a sixth via V6 that extends through the sixth insulation layer 109 and the fifth insulation layer 108. This facilitates the connection of the data writing transistor T1 to the data transmission lines Data, the data writing transistor T1 may transmit a data voltage Vdata on the data transmission lines Data to the control electrode of the drive transistor T4, enabling the drive transistor T4 to generate a drive current based on the data voltage Vdata.

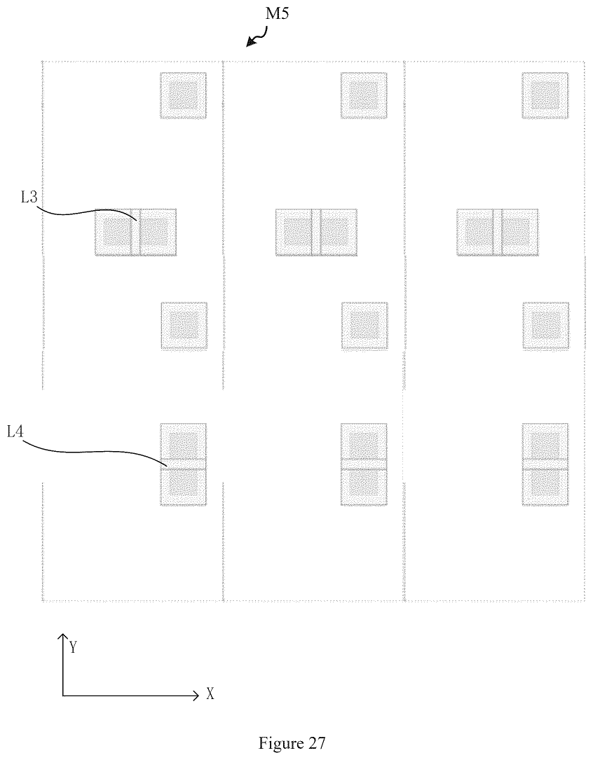

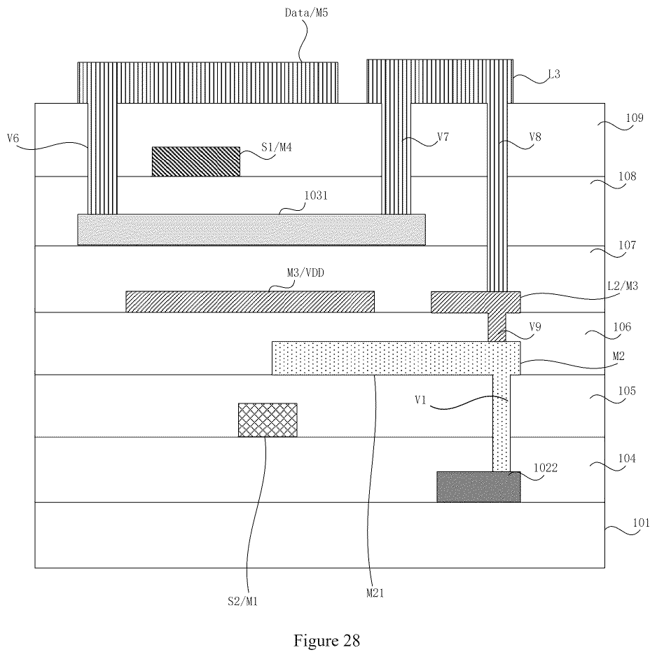

FIG. 27 is a schematic view of a layout structure of a fifth conductive layer of an array substrate according to an embodiment of the present disclosure, and FIG. 28 is a sectional view of FIG. 14 taken along line h1-h2. Referring to FIGS. 26, 27, and 28, the fifth conductive layer M5 further includes a third connection portion L3 extending in the first direction X and a fourth connection portion L4 extending in the second direction Y, the second electrode of the data writing transistor T1 is connected to the third connection portion L3 through a seventh via V7, an end of the third connection portion L3 away from the seventh via V7 is connected to the second connection portion L2 through an eighth via V8, and the second connection portion L2 is connected to the second electrode of the coupling capacitor C1 through a ninth via V9, where
the seventh via V7 extends through the sixth insulation layer 109 and the fifth insulation layer 108, the eighth via V8 extends through the sixth insulation layer 109, the fifth insulation layer 108, and the fourth insulation layer 107, and the ninth via V9 extends through the third insulation layer 106. This facilitates the connection of the data writing transistor T1 to the second electrode of the coupling capacitor C1.

Referring to FIG. 28, an orthographic projection of the ninth via V9 on the base substrate 101 overlaps with an orthographic projection of the first via V1 on the base substrate. In this way, the space utilization may be increased, which is conducive to increasing the pixel density of the display panel formed by the array substrate.

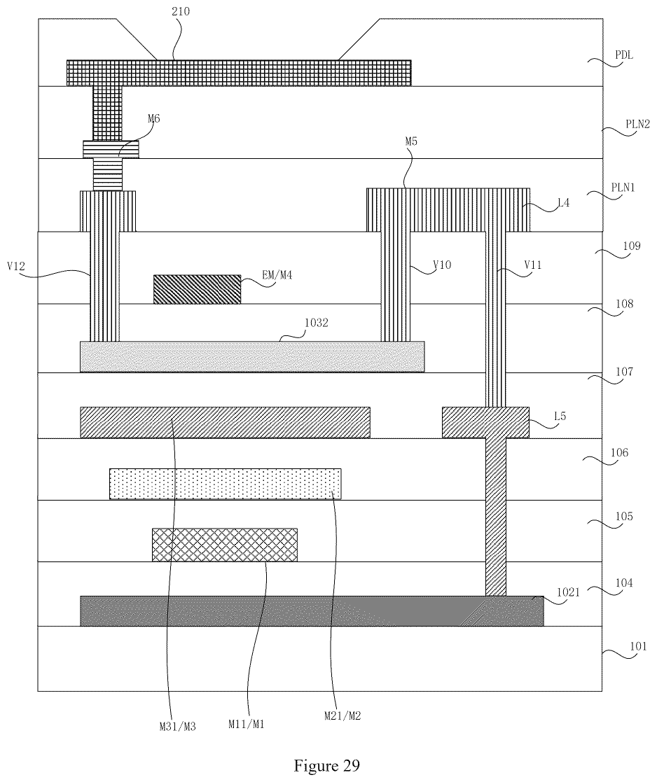

FIG. 29 is a sectional view of FIG. 14 taken along line h3-h4. referring to FIGS. 26 and 29, a first electrode of the light emission control transistor T5 is connected to the fourth connection portion L4 through a tenth via V10, and an end of the fourth connection portion L4 away from the tenth via V10 is connected to a fifth connection portion L5 through an eleventh via V11, where
the tenth via V10 sequentially extends through the sixth insulation layer 109 and the fifth insulation layer 108, and the eleventh via V11 sequentially extends through the sixth insulation layer 109, the fifth insulation layer 108, and the fourth insulation layer 107. This facilitates the connection of the light emission control transistor T5 to the drive transistor T4.

As shown in FIG. 29, a second electrode of the light emission control transistor T5 is electrically connected to a first electrode 210 of a light-emitting element 200 through a twelfth via V12 that extends through the sixth insulation layer 109 and the fifth insulation layer 108. This facilitates the connection of the light emission control transistor T5 to the first electrode 210 of the light-emitting element 200. Here, the first electrode 210 of the light-emitting element 210 is a first terminal of the light-emitting element 200. The first electrode 210 of the light-emitting element 200 is an anode or a cathode.

As shown in FIG. 29, the array substrate further includes a first planarization layer PLN1 located on a side of the fifth conductive layer M5 facing away from the base substrate 101, a sixth conductive layer M6 located on a side of the first planarization layer PLN1 facing away from the base substrate 101, a second planarization layer PLN2 located on a side of the sixth conductive layer M6 facing away from the base substrate 101, and a pixel define layer PDL located on a side of the second planarization layer PLN2 facing away from the base substrate 101. Here, the pixel define layer PDL is configured to define a size of the light-emitting element 200. The first electrode 210 of the light-emitting element 200 is connected to the second electrode of the light emission control transistor T5 through a conductive connection portion located in the sixth conductive layer M6.

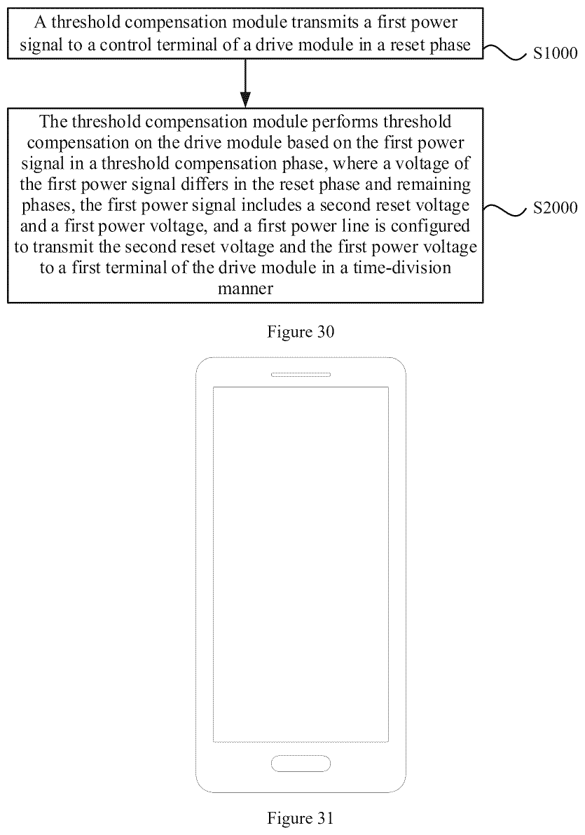

An embodiment of the present disclosure further provides a driving method for a pixel circuit, which is used to drive the pixel circuit according to any one of the embodiments of the present disclosure. FIG. 30 is a flowchart of a driving method for a pixel circuit according to an embodiment of the present disclosure. Referring to FIG. 30, the driving method for a pixel circuit includes the following steps.

S1000: A threshold compensation sub-circuit transmits a first power signal to a control terminal of a drive sub-circuit in a reset phase.

A first power line VDD is configured to transmit the first power signal. A voltage of the first power signal is set to differ in at least two drive phases, the first power line VDD may transmit different voltages in a time-division manner. The first power signal includes a second reset voltage and a first power voltage. For example, in the reset phase, the first power signal is at the second reset voltage, and the second reset voltage is transmitted to the control terminal of the drive sub-circuit 110 through the drive sub-circuit 110 and the threshold compensation sub-circuit 120, to reset the control terminal of the drive sub-circuit 110, that is, the threshold compensation sub-circuit 120 resets the drive sub-circuit 110.

S2000: The threshold compensation sub-circuit performs threshold compensation on the drive sub-circuit based on the first power signal in a threshold compensation phase.

The voltage of the first power signal differs in the reset phase and remaining phases, the first power signal includes the second reset voltage and the first power voltage, and the first power line is configured to transmit the second reset voltage and the first power voltage to a first terminal of the drive sub-circuit in a time-division manner.

In the threshold compensation phase, the first power signal is at the first power voltage, and the first power voltage charges the control terminal of the drive sub-circuit 110 through the drive sub-circuit 110 and the threshold compensation sub-circuit 120, and a voltage at the control terminal of the drive sub-circuit 110 is a voltage related to both the first power voltage and a threshold voltage of a transistor in the drive sub-circuit 110, thereby implementing threshold compensation on the drive sub-circuit 110, that is, the threshold compensation sub-circuit 120 performs threshold compensation on the drive sub-circuit 110. In this way, the threshold compensation sub-circuit 120 resets the drive sub-circuit 110 and performs threshold compensation on the drive sub-circuit in a time-division manner. As a result, there is no need to provide a large number of sub-circuits to achieve compensation and reset, which reduces a number of transistors and is conducive to increasing the pixel density of a display panel corresponding to the pixel circuit. Therefore, it is ensured that reset and compensation can be performed on the pixel circuit with fewer components in the pixel circuit. This means that the normal operation of the pixel circuit is ensured while maintaining a high pixel density of the display panel, thereby improving the use performance of the display panel.

On the basis of the above-mentioned embodiment, in the reset phase, the first power signal is at the second reset voltage, and in the remaining phases, the first power signal is at the first power voltage.

The threshold compensation sub-circuit transmitting the first power signal to the control terminal of the drive sub-circuit in the reset phase includes:
the threshold compensation sub-circuit transmitting the second reset voltage to the control terminal of the drive sub-circuit in the reset phase.

In the reset phase, the first power signal is at the second reset voltage, and the second reset voltage is transmitted to the control terminal of the drive sub-circuit 110 through the drive sub-circuit 110 and the threshold compensation sub-circuit 120, to reset the control terminal of the drive sub-circuit 110, that is, the threshold compensation sub-circuit 120 resets the drive sub-circuit 110.

The threshold compensation sub-circuit performing threshold compensation on the drive sub-circuit based on the first power signal in the threshold compensation phase includes:
The threshold compensation sub-circuit performing threshold compensation on the drive sub-circuit based on the first power voltage in the threshold compensation phase.

In the threshold compensation phase, the first power signal is at the first power voltage, and the first power voltage charges the control terminal of the drive sub-circuit 110 through the drive sub-circuit 110 and the threshold compensation sub-circuit 120, and a voltage at the control terminal of the drive sub-circuit 110 is a voltage related to both the first power voltage and a threshold voltage of a transistor in the drive sub-circuit 110, thereby implementing threshold compensation on the drive sub-circuit 110, that is, the threshold compensation sub-circuit 120 performs threshold compensation on the drive sub-circuit 110. In this way, the threshold compensation sub-circuit 120 resets the drive sub-circuit 110 and performs threshold compensation on the drive sub-circuit in a time-division manner.

On the basis of the above-mentioned embodiment, in the reset phase, the threshold compensation sub-circuit transmits the first power signal to the control terminal of the drive sub-circuit, and a data writing sub-circuit transmits a first reset voltage to a coupling sub-circuit. This process includes the following steps:
Step a11: A voltage of the first power signal jumps from the first power voltage to the second reset voltage in a first sub-phase of the reset phase.
Step a12: The threshold compensation sub-circuit transmits the second reset voltage to the control terminal of the drive sub-circuit in a second sub-phase of the reset phase, to reset the control terminal of the drive sub-circuit.
Step a13: The data writing sub-circuit transmits the first reset voltage to the coupling sub-circuit in a third sub-phase of the reset phase.

In the first sub-phase of the reset phase, the voltage of the first power signal jumps from the first power voltage to the second reset voltage, that is, at the beginning of the reset phase, the first power signal changes to the second reset voltage, to reset the drive sub-circuit 110 based on the second reset voltage. After the first power signal changes to the second reset voltage, the threshold compensation sub-circuit 120 transmits the second reset voltage to the control terminal of the drive sub-circuit 110 in the second sub-phase of the reset phase, that is, the second reset voltage is transmitted to the control terminal of the drive sub-circuit 110 through the drive sub-circuit 110 and the threshold compensation sub-circuit 120, which can clear a residual voltage at the control terminal of the drive sub-circuit 110, thereby resetting the drive sub-circuit 110. In the third sub-phase, the first reset voltage Vini is transmitted to the coupling sub-circuit 140. For example, if the drive sub-circuit 110 needs to be reset at a low voltage, and the first reset voltage Vini is greater than the second reset voltage, in the third sub-phase and with the coupling effect of the coupling sub-circuit 140, the voltage at the control terminal of the drive sub-circuit 110 is slightly pulled up but still remains at a low voltage, to reset the control terminal of the drive sub-circuit 110.

The second reset voltage is less than the first reset voltage.

In one reset phase, a duration of the second sub-phase is greater than a duration of the third sub-phase.

In one reset phase, the duration of the second sub-phase is greater than a duration of the first sub-phase.

An embodiment of the present disclosure further provides a display panel. FIG. 31 is a schematic structural diagram of a display panel according to an embodiment of the present disclosure. As shown in FIG. 31, the display panel includes the array substrate according to any one of the embodiments. The display panel may be a cell phone, a tablet computer, a television, a display, a laptop computer, a digital photo frame, or any product or component having a display function. The display panel includes the array substrate according to any embodiment of the present disclosure, and therefore, exhibits the same beneficial effects as the array substrate according to any embodiment of the present disclosure, which will not be repeated here.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the scope of protection of the present disclosure. Various modifications, combinations, sub-combinations, and substitutions can be made based on design requirements and other factors. Any modifications, equivalent substitutions, or improvements made within the spirit and principle of the present disclosure should be included within the scope of protection of the present disclosure.

1. A pixel circuit, comprising:
a drive sub-circuit, a first terminal of the drive sub-circuit being connected to a first power line, and the first power line transmitting a first power signal to the drive sub-circuit; and
a threshold compensation sub-circuit, the threshold compensation sub-circuit being connected to a second terminal of the drive sub-circuit and a control terminal of the drive sub-circuit, and the threshold compensation sub-circuit being configured to reset the drive sub-circuit and perform threshold compensation on the drive sub-circuit in a time-division manner, wherein
in a same display frame, the first power line is configured to transmit a second reset voltage and a first power voltage to the first terminal of the drive sub-circuit in a time-division manner.

2. The pixel circuit according to claim 1, wherein
in a reset phase of the same display frame, the first power signal is at the second reset voltage, and in remaining phases of the same display frame, the first power signal is at the first power voltage.

3. The pixel circuit according to claim 1, wherein a reset phase of the same display frame comprises a first sub-phase and a second sub-phase;
a voltage of the first power signal jumps from the first power voltage to the second reset voltage in the first sub-phase;
the threshold compensation sub-circuit is configured to transmit the second reset voltage to the control terminal of the drive sub-circuit in the second sub-phase, to reset the control terminal of the drive sub-circuit; and
in the same display frame, the second sub-phase is later than the first sub-phase.

4. The pixel circuit according to claim 1, wherein the same display frame further comprises a threshold compensation phase in which a voltage of the first power signal jumps from the second reset voltage to the first power voltage.

5. The pixel circuit according to claim 3, wherein the pixel circuit further comprises a data writing sub-circuit and a coupling sub-circuit, a first terminal of the data writing sub-circuit being connected to a data voltage and a first reset voltage, the coupling sub-circuit being connected between a second terminal of the data writing sub-circuit and the control terminal of the drive sub-circuit, and the data writing sub-circuit being configured to transmit the data voltage and the first reset voltage to the coupling sub-circuit in a time-division manner, wherein
the second reset voltage is less than the first reset voltage.

6. The pixel circuit according to claim 5, wherein the reset phase further comprises a third sub-phase, wherein
the data writing sub-circuit is configured to transmit the first reset voltage to the coupling sub-circuit in the third sub-phase, to reset the control terminal of the drive sub-circuit through the coupling sub-circuit;
in the same display frame, the third sub-phase is later than a second sub-phase;
in the same display frame, a duration of the second sub-phase is greater than a duration of the third sub-phase; and
in the same display frame, the duration of the second sub-phase is greater than a duration of the first sub-phase.

7. The pixel circuit according to claim 5, wherein the data writing sub-circuit comprises a data writing transistor, a first electrode of the data writing transistor being connected to the data voltage and the first reset voltage, a second electrode of the data writing transistor being connected to the coupling sub-circuit, a control electrode of the data writing transistor being connected to a first scan line, and the data writing transistor being configured to transmit the data voltage and the first reset voltage to the coupling sub-circuit in a time-division manner, wherein
the data writing transistor is configured to transmit the data voltage to the coupling sub-circuit in a data writing phase, and the data writing transistor is configured to transmit the first reset voltage to the coupling sub-circuit in a third sub-phase of the reset phase; and
the second reset voltage is less than the first reset voltage.

8. The pixel circuit according to claim 5, wherein the data writing sub-circuit comprises a data writing transistor and a reset transistor, wherein
a control electrode of the data writing transistor is connected to a first scan line, a first electrode of the data writing transistor is connected to the data voltage, a second electrode of the data writing transistor is connected to the coupling sub-circuit, the data writing transistor is configured to transmit the data voltage to the coupling sub-circuit in a data writing phase, and the coupling sub-circuit is configured to couple the data voltage to the control terminal of the drive sub-circuit; and
a first electrode of the reset transistor is connected to the first reset voltage, a second electrode of the reset transistor is connected to the coupling sub-circuit, and the reset transistor is configured to transmit the first reset voltage to the coupling sub-circuit in a third sub-phase of the reset phase.

9. The pixel circuit according to claim 8, wherein a control electrode of the reset transistor is connected to a second scan line;
the threshold compensation sub-circuit comprises a threshold compensation transistor, a control electrode of the threshold compensation transistor being connected to a third scan line, and the threshold compensation transistor being connected between the second terminal of the drive sub-circuit and the control terminal of the drive sub-circuit; and
the threshold compensation transistor and the reset transistor are both N-type or P-type transistors.

10. The pixel circuit according to claim 9, wherein the second scan line is configured to transmit a second scan signal, and the third scan line is configured to transmit a third scan signal; and in the same display frame, a start time of an effective level of the second scan signal is delayed by one row time relative to a start time of an effective level of the third scan signal; and
a period of the second scan signal is the same as a period of the third scan signal, and a waveform of the second scan signal is the same as a waveform of the third scan signal.

11. The pixel circuit according to claim 9, wherein the second scan line and the third scan line extend in a first direction, and among two pixel circuits adjacent in a second direction, a third scan line corresponding to one pixel circuit is connected to a second scan line corresponding to the other pixel circuit, the first direction intersecting the second direction.

12. The pixel circuit according to claim 5, wherein the drive sub-circuit comprises a drive transistor, a control electrode of the drive transistor being connected to the coupling sub-circuit, a first electrode of the drive transistor being connected to the first power signal, and a second electrode of the drive transistor being connected to the threshold compensation sub-circuit;
the coupling sub-circuit comprises a coupling capacitor, a first electrode of the coupling capacitor being connected to the control electrode of the drive transistor, and a second electrode of the coupling capacitor being connected to the data writing sub-circuit;
the pixel circuit further comprises a storage sub-circuit, wherein
a first terminal of the storage sub-circuit is connected to the first power signal, and a second terminal of the storage sub-circuit is connected to a second terminal of the coupling sub-circuit or the control terminal of the drive sub-circuit;
a first terminal of the coupling sub-circuit is connected to the control terminal of the drive sub-circuit;
the pixel circuit further comprises a light emission control sub-circuit, a control terminal of the light emission control sub-circuit being connected to a light emission control line, and the light emission control sub-circuit being connected between the second terminal of the drive sub-circuit and a light-emitting element;
the storage sub-circuit comprises a storage capacitor, a first electrode of the storage capacitor being connected to the first power signal, and a second electrode of the storage capacitor being connected to the second terminal of the coupling sub-circuit; and
the light emission control sub-circuit comprises a light emission control transistor, a control electrode of the light emission control transistor being connected to the light emission control line, and the light emission control transistor being connected between the second terminal of the drive sub-circuit and the light-emitting element.

13. The pixel circuit according to claim 7, wherein
the drive sub-circuit comprises a drive transistor, an active layer of the drive transistor and an active layer of the data writing transistor being made of different materials; and
the active layer of the drive transistor comprises a polysilicon semiconductor material, and the active layer of the data writing transistor comprises an oxide semiconductor material.

14. An array substrate, comprising:
a base substrate;
a first active layer located on a side of the base substrate, the first active layer comprising a first active region, and the first active region being provided with a channel region of a drive transistor and a channel region of a threshold compensation transistor;
a first conductive layer located on a side of the first active layer facing away from the base substrate, the first conductive layer comprising a first metal block forming a control electrode of the drive transistor and a third scan line forming a control electrode of the threshold compensation transistor, the third scan line extending in a first direction, the channel region of the drive transistor being located at an orthographic projection of the first metal block on the first active region, the channel region of the threshold compensation transistor being located at an orthographic projection of the third scan line on the first active region, the first metal block being connected to a first electrode of the threshold compensation transistor through a first connection portion, and a second electrode of the drive transistor being connected to a second electrode of the threshold compensation transistor through the first active region;
a second conductive layer located on a side of the first conductive layer facing away from the base substrate, the second conductive layer comprising a second metal block forming a second electrode of a coupling capacitor, the first metal block being reused as a first electrode of the coupling capacitor, and an orthographic projection of the second metal block on the base substrate covering an orthographic projection of the first metal block on the base substrate;
a second active layer located on a side of the second conductive layer facing away from the base substrate, the second active layer comprising a third active region, and the third active region being provided with a channel region of a data writing transistor; and
a fourth conductive layer located on a side of the second active layer facing away from the base substrate, the fourth conductive layer comprising a first scan line forming a control electrode of the data writing transistor, the first scan line extending in the first direction, the channel region of the data writing transistor being located at an orthographic projection of the first scan line on the third active region, and a second electrode of the data writing transistor being connected to the second metal block through a second connection portion, wherein
the first active layer and the second active layer are made of different materials.

15. The array substrate according to claim 14, wherein the first active layer further comprises a second active region, the second active region comprises a channel region of a reset transistor, and a second electrode of the reset transistor being connected to the second electrode of the coupling capacitor;
the first conductive layer further comprises a second scan line extending in the first direction, and the channel region of the reset transistor is located at an orthographic projection of the second scan line on the second active region;
an extension direction of the channel region of the threshold compensation transistor is arranged perpendicular to an extension direction of the channel region of the reset transistor;
in a second direction, the channel region of the threshold compensation transistor and the channel region of the reset transistor are distributed on two sides of the channel region of the drive transistor, the first direction intersects with the second direction;
the first metal block comprises a first protrusion, the first protrusion being located at an end of the first metal block facing the threshold compensation transistor, and the first electrode of the threshold compensation transistor being connected to the first protrusion; and
the second metal block comprises a second protrusion, the second protrusion being located at an end of the second metal block facing the reset transistor, and the second electrode of the reset transistor being electrically connected to the second protrusion.

16. The array substrate according to claim 15, wherein
the second active layer further comprises a fourth active region, the fourth active region comprises a channel region of a light emission control transistor, and the third active region and the fourth active region being spaced apart and each extending in the second direction;
an orthographic projection of the third active region on the base substrate and an orthographic projection of the fourth active region on the base substrate both partially overlap with an orthographic projection of the first active region on the base substrate;
the fourth conductive layer further comprises a light emission control line extending in the first direction, and the channel region of the light emission control transistor is located at an orthographic projection of the light emission control line on the fourth active region; and
the channel region of the drive transistor is II-shaped, and the third active region is L-shaped.

17. The array substrate according to claim 16, wherein the array substrate further comprises a third conductive layer located between the second conductive layer and the second active layer;
the third conductive layer comprises a third metal block forming a first electrode of a storage capacitor, an orthographic projection of the third metal block on the base substrate covers the orthographic projection of the second metal block on the base substrate, and the second metal block being reused as a second electrode of the storage capacitor;
in the first direction, adjacent third metal blocks are interconnected, the interconnected third metal blocks being reused as a first power line to transmit a first power signal, and the first electrode of the storage capacitor being connected to a first electrode of the drive transistor;
the third metal block comprises a third protrusion, the third protrusion extending toward the third active region;
the first connection portion and the second connection portion are both located in the third conductive layer;
the orthographic projection of the third active region on the base substrate and the orthographic projection of the fourth active region on the base substrate are within the orthographic projection of the third metal block on the base substrate;
the third scan line comprises a body portion and an extension portion, the body portion has a same extension direction as that of the channel region of the threshold compensation transistor, an extension direction of the extension portion being arranged perpendicular to the extension direction of the body portion, and the channel region of the threshold compensation transistor being located at an orthographic projection of the extension portion on the first active region; and
the body portion has a same width as that of the first scan line.

18. The array substrate according to claim 17, wherein the second conductive layer further comprises a plurality of reset power signal lines extending in the first direction, an orthographic projection of the reset power signal lines on the base substrate partially overlapping with an orthographic projection of a first electrode of the reset transistor on the base substrate, and the first electrode of the reset transistor being connected to the reset power signal line; or
the third conductive layer further comprises a plurality of reset power signal lines, an orthographic projection of the reset power signal lines on the base substrate partially overlapping with an orthographic projection of a first electrode of the reset transistor on the base substrate, and the first electrode of the reset transistor being connected to the reset power signal line; and
an end of the second active region away from the second metal block is electrically connected to one of the reset power signal lines.

19. The array substrate according to claim 18, wherein the array substrate further comprises a first insulation layer located between the first active layer and the first conductive layer, a second insulation layer located between the first conductive layer and the second conductive layer, and a third insulation layer located between the second conductive layer and the third conductive layer;
the second electrode of the reset transistor is connected to the second metal block through a first via that extends through the first insulation layer and the second insulation layer, and the first electrode of the reset transistor is connected to the reset power signal line through a second via, the second via extends through the first insulation layer and the second insulation layer, or the second via extends through the first insulation layer, the second insulation layer, and the third insulation layer;
the first electrode of the drive transistor is connected to the third metal block through a third via, the third via extends through the first insulation layer, the second insulation layer, and the third insulation layer;
the control electrode of the drive transistor is connected to the first connection portion through a fourth via, and the first connection portion is further connected to the first electrode of the threshold compensation transistor through a fifth via; and
the fourth via extends through the second insulation layer and the third insulation layer, and the fifth via sequentially extends through the third insulation layer, the second insulation layer, and the first insulation layer.

20. The array substrate according to claim 19, wherein the array substrate further comprises a fourth insulation layer located between the third conductive layer and the second active layer, a fifth insulation layer located between the second active layer and the fourth conductive layer, and a sixth insulation layer located on a side of the fourth conductive layer facing away from the base substrate;
the fifth conductive layer comprises a plurality of data transmission lines extending in the second direction, and a first electrode of the data writing transistor is connected to the data transmission lines through a sixth via, the sixth via extends through the sixth insulation layer and the fifth insulation layer;
the fifth conductive layer further comprises a third connection portion extending in the first direction and a fourth connection portion extending in the second direction, the second electrode of the data writing transistor is connected to the third connection portion through a seventh via, an end of the third connection portion away from the seventh via is connected to the second connection portion through an eighth via, and the second connection portion is connected to the second electrode of the coupling capacitor through a ninth via;
the eighth via sequentially extends through the sixth insulation layer, the fifth insulation layer, and the fourth insulation layer, the seventh via extends through the sixth insulation layer and the fifth insulation layer, and the ninth via extends through the third insulation layer;
an orthographic projection of the ninth via on the base substrate overlaps with an orthographic projection of the first via on the base substrate;
a first electrode of the light emission control transistor is connected to the fourth connection portion through a tenth via, and an end of the fourth connection portion away from the tenth via is connected to a fifth connection portion through an eleventh via;
the tenth via sequentially extends through the sixth insulation layer and the fifth insulation layer, and the eleventh via sequentially extends through the sixth insulation layer, the fifth insulation layer, and the fourth insulation layer; and
a second electrode of the light emission control transistor is electrically connected to a first electrode of a light-emitting element through a twelfth via that extends through the sixth insulation layer and the fifth insulation layer.
